(19) United States
(12) Patent Application Publication
(10) Pub. No.: US 2025/0252238 A1
(43) Pub. Date: Aug. 7, 2025

(54) APPARATUS AND METHOD FOR GENERATING A RESERVOIR MODEL

(71) Applicant: David Cook, Lakeway, TX (US)

(72) Inventor: David Cook, Lakeway, TX (US)

(21) Appl. No.: 18/433,159

(22) Filed: Feb. 5, 2024

(51) Int. Cl. G06F 30/28

(52) U.S. Cl. CPC G06F 30/28

(57) ABSTRACT

In an aspect, an apparatus for generating a reservoir model is disclosed. The apparatus includes at least a processor and memory communicatively connected to the at least a processor. The memory instructs the processor to receive a condition data associated with a target well. The memory instructs the processor to generate a plurality of reservoir conditions associated with the target well as a function of the condition data. The memory instructs the processor to identify a plurality of flagged data as a function of the plurality of reservoir conditions. The memory instructs the processor to predict reservoir geometry associated with the target well as a function of the plurality of flagged data.

### FIELD OF THE INVENTION

The present invention generally relates to the field of natural resource extraction. In particular, the present invention is directed to an apparatus and a method for generating a reservoir model.

### BACKGROUND

There are significant differences in natural resource production after large-scale fracking of horizontal wells due to a plurality of reservoir properties. Fracking optimization is very important for low permeability reservoir stimulation and development in natural resource extraction. A solution to optimize the fracking process is needed to maximize natural resource harvesting.

### SUMMARY OF THE DISCLOSURE

In an aspect, an apparatus for generating a reservoir model is disclosed. The apparatus includes at least a processor and memory communicatively connected to the at least a processor. The memory instructs the processor to receive a condition data associated with a target well. The memory instructs the processor to generate a plurality of reservoir conditions associated with the target well as a function of the condition data. The memory instructs the processor to identify a plurality of flagged data as a function of the plurality of reservoir conditions. The memory instructs the processor to predict reservoir geometry associated with the target well as a function of the plurality of flagged data.

In another aspect, a method for generating a reservoir model is disclosed. The method includes receiving, using at least a processor, a condition data associated with a target well. The method also includes generating, using the at least a processor, a plurality of reservoir conditions associated with the target well as a function of the condition data. The method includes identifying, using the at least a processor, a plurality of flagged data as a function of the plurality of reservoir conditions. The method includes predicting, using the at least a processor, reservoir geometry associated with the target well as a function of the plurality of flagged data.

These and other aspects and features of non-limiting embodiments of the present invention will become apparent to those skilled in the art upon review of the following description of specific non-limiting embodiments of the invention in conjunction with the accompanying drawings.

### BRIEF DESCRIPTION OF THE DRAWINGS

For the purpose of illustrating the invention, the drawings show aspects of one or more embodiments of the invention. However, it should be understood that the present invention is not limited to the precise arrangements and instrumentalities shown in the drawings, wherein:

FIG. 1 is a block diagram of an exemplary embodiment of an apparatus for generating a reservoir model;

FIG. 2 is a block diagram of an exemplary machine-learning process;

FIG. 3 is a block diagram of an exemplary embodiment of a reservoir database;

FIG. 4 is a diagram of an exemplary embodiment of a neural network;

FIG. 5 is a diagram of an exemplary embodiment of a node of a neural network;

FIG. 6 is an illustration of an exemplary embodiment of fuzzy set comparison;

FIG. 7 is a flow diagram of an exemplary method for generating a reservoir model; and

FIG. 8 is a block diagram of a computing system that can be used to implement any one or more of the methodologies disclosed herein and any one or more portions thereof.

The drawings are not necessarily to scale and may be illustrated by phantom lines, diagrammatic representations, and fragmentary views. In certain instances, details that are not necessary for an understanding of the embodiments or that render other details difficult to perceive may have been omitted.

### DETAILED DESCRIPTION

At a high level, aspects of the present disclosure are directed to an apparatus and a method for generating a reservoir model is disclosed. The apparatus includes at least a processor and memory communicatively connected to the at least a processor. The memory instructs the processor to receive a condition data associated with a target well. The memory instructs the processor to generate a plurality of reservoir conditions associated with the target well as a function of the condition data. The memory instructs the processor to identify a plurality of flagged data as a function of the plurality of reservoir conditions. The memory instructs the processor to predict reservoir conditions associated with the target well as a function of the plurality of flagged data. Exemplary embodiments illustrating aspects of the present disclosure are described below in the context of several specific examples.

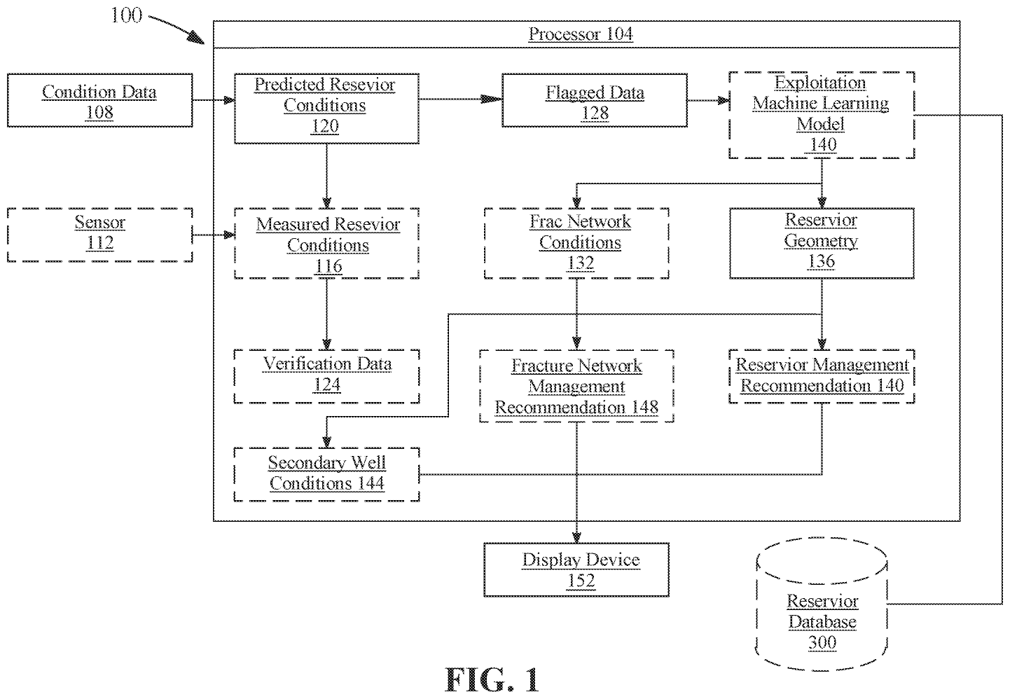

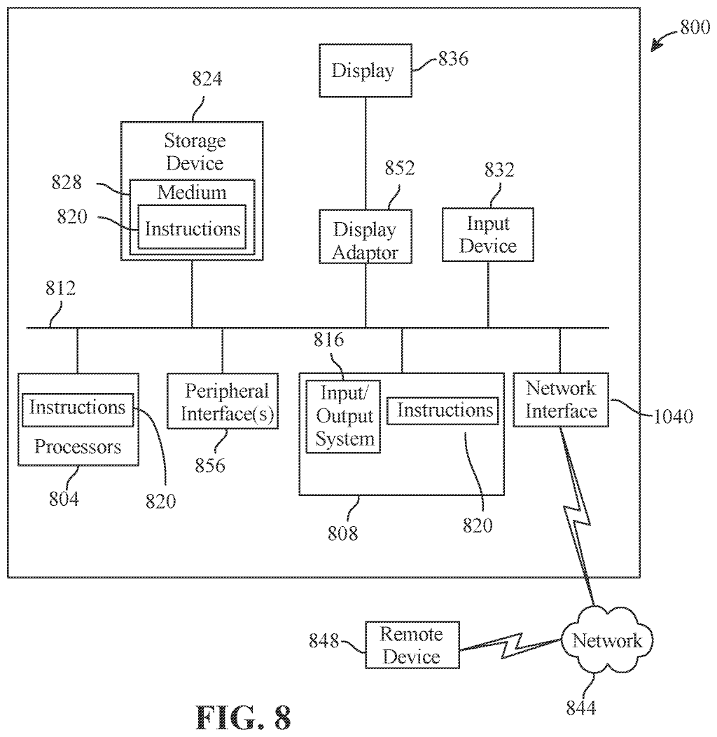

Referring now to FIG. 1, an exemplary embodiment of an apparatus 100 for generating a reservoir model is illustrated. Apparatus 100 includes a processor 104. Processor 104 may include any computing device as described in this disclosure, including without limitation a microcontroller, microprocessor, digital signal processor (DSP) and/or system on a chip (SoC) as described in this disclosure. In one or more embodiments, computing device may include, be included in, or be communicatively connected to computing system 800 of FIG. 8. Computing device may include, be included in, and/or communicate with a mobile device such as a mobile telephone or smartphone. Processor 104 may include a single computing device operating independently, or may include two or more computing device operating in concert, in parallel, sequentially or the like; two or more computing devices may be included together in a single computing device or in two or more computing devices. Processor 104 may interface or communicate with one or more additional devices as described below in further detail via a network interface device. Network interface device may be utilized for connecting processor 104 to one or more of a variety of networks, and one or more devices. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus, or other relatively small geographic space), a telephone network, a data network associated with a telephone/voice provider (e.g., a mobile communications provider data and/or voice network), a direct connection between two computing devices, and any combinations thereof. A network may employ a wired and/or a wireless mode of communication. In general, any network topology may be used. Information (e.g., data, software etc.) may be communicated to and/or from a computer and/or a computing device. Processor 104 may include but is not limited to, for example, a computing device or cluster of computing devices in a first location and a second computing device or cluster of computing devices in a second location. Processor 104 may include one or more computing devices dedicated to data storage, security, distribution of traffic for load balancing, and the like. Processor 104 may distribute one or more computing tasks as described below across a plurality of computing devices of computing device, which may operate in parallel, in series, redundantly, or in any other manner used for distribution of tasks or memory between computing devices. Processor 104 may be implemented using a “shared nothing” architecture in which data is cached at the worker, in an embodiment, this may enable scalability of apparatus 100 and/or computing device.

With continued reference to FIG. 1, processor 104 may be designed and/or configured to perform any method, method step, or sequence of method steps in any embodiment described in this disclosure, in any order and with any degree of repetition. For instance, processor 104 may be configured to perform a single step or sequence repeatedly until a desired or commanded outcome is achieved; repetition of a step or a sequence of steps may be performed iteratively and/or recursively using outputs of previous repetitions as inputs to subsequent repetitions, aggregating inputs and/or outputs of repetitions to produce an aggregate result, reduction or decrement of one or more variables such as global variables, and/or division of a larger processing task into a set of iteratively addressed smaller processing tasks. Specifically, this may include iteratively training any machine learning model. This may include using the inputs and outputs of the machine learning model gradually make improvements to the outputs of a machine learning model. Processor 104 may perform any step or sequence of steps as described in this disclosure in parallel, such as simultaneously and/or substantially simultaneously performing a step two or more times using two or more parallel threads, processor cores, or the like; division of tasks between parallel threads and/or processes may be performed according to any protocol suitable for division of tasks between iterations. Persons skilled in the art, upon reviewing the entirety of this disclosure, will be aware of various ways in which steps, sequences of steps, processing tasks, and/or data may be subdivided, shared, or otherwise dealt with using iteration, recursion, and/or parallel processing.

With continued reference to FIG. 1, apparatus 100 includes a memory. Memory is communicatively connected to processor 104. Memory may contain instructions configuring processor 104 to perform tasks disclosed in this disclosure. As used in this disclosure, “communicatively connected” means connected by way of a connection, attachment, or linkage between two or more relata which allows for reception and/or transmittance of information therebetween. For example, and without limitation, this connection may be wired or wireless, direct, or indirect, and between two or more components, circuits, devices, systems, apparatus, and the like, which allows for reception and/or transmittance of data and/or signal(s) therebetween. Data and/or signals therebetween may include, without limitation, electrical, electromagnetic, magnetic, video, audio, radio, and microwave data and/or signals, combinations thereof, and the like, among others. A communicative connection may be achieved, for example, and without limitation, through wired or wireless electronic, digital, or analog, communication, either directly or by way of one or more intervening devices or components. Further, communicative connection may include electrically coupling or connecting at least an output of one device, component, or circuit to at least an input of another device, component, or circuit. For example, without limitation, via a bus or other facility for intercommunication between elements of a computing device. Communicative connecting may also include indirect connections via, for example, and without limitation, wireless connection, radio communication, low power wide area network, optical communication, magnetic, capacitive, or optical coupling, and the like. In some instances, the terminology “communicatively coupled” may be used in place of communicatively connected in this disclosure.

With continued reference to FIG. 1, processor 104 may be configured to receive a condition data 108. As used in the current disclosure, “condition data” is an element of datum or data related to conditions associated with a well. Conditions may refer to any conditions that do not occur downhole. Conditions may also refer to any surface level condition surrounding the target well or reservoir. These conditions may include rock properties, fluid properties, treatment parameters, soil conditions, soil conditions, environmental conditions, environmental conditions, seismic data, fluid composition, well integrity data, surface equipment condition, and the like. Condition data 108 may include to specific information or measurements related to various conditions associated with a well in the oil and gas industry. These conditions pertain to factors that are not located downhole, meaning they are not occurring deep within the wellbore or reservoir. Instead, they encompass a wide range of surface and near-surface conditions that can influence the well's performance and operations. The condition data plays a crucial role in well management, optimization, and decision-making processes. Condition data 108 may be received from a user or a drilling entity. Condition data 108 may be received from a database. In some embodiments, a condition data may be generated using a v-lookup table. As used in the current disclosure, “v-lookup” refers to a method of searching and retrieving data from a specific column within a table based on a given lookup value. V-lookup is a built-in function in spreadsheet software that automates this process. Condition data may be generated and/or detected using a plurality of condition data sensors. As used in the current disclosure, a “condition data sensor” is a sensor used to determine condition data 108. A condition data sensor may be similar to sensor 112 discussed in greater detail herein below. Condition data sensors may be configured to sense system geometry, geographical information, temporal information, current operation datum, and the like. In an embodiment, a condition data sensor may be configured to detect the location and orientation of the fracking equipment. In another embodiment, a condition data sensor may be configured to provide processor 104 with the geographic location of the target well. In some cases, processor 104 may identify any previous fracking activity within target well or within a geographic range as a function of the geographic location. Condition data sensors may comprise global positioning systems, cameras, time measurement devices, pressure sensors, viscosity sensors, temperature sensors, and the like.

With continued reference to FIG. 1, condition data 108 may include rock properties. As used in the current disclosure, “rock properties” refer to characteristics and behavior of the underground rock formations that are targeted for oil and gas extraction. Understanding these properties is crucial for designing and optimizing the hydraulic fracturing process to effectively stimulate the reservoir and maximize hydrocarbon recovery. Rock properties may include rock porosity, permeability, reservoir pressure, young's modulus and poisson's ratio, fracture toughness, brittleness, mineralogy and composition, mineralogy and composition, anisotropy, natural fractures, and the like. For example, porosity refers to the percentage of pore space within the rock. It represents the volume of voids or openings that can contain fluids, such as natural gas, oil, or water. Higher porosity allows for more hydrocarbons to be stored in the rock. Additionally, permeability may refer to the ability of the rock to allow fluids to flow through it. It is a measure of how easily fluids can move within the rock's pore spaces. High permeability is desirable for efficient hydrocarbon extraction.

With continued reference to FIG. 1, condition data 108 may include treatment parameters. As used in the current disclosure, “treatment parameters” refer to the specific operational variables and conditions that are controlled and adjusted during the fracturing process. These parameters are crucial in designing and executing an effective and efficient hydraulic fracturing operation to maximize hydrocarbon recovery from the reservoir. Various treatment parameters are carefully considered and monitored to optimize the result. Examples of treatment parameters may include information regarding injection rate, injection pressure, proppant concentration, fracture stage spacing, fracture fluid volume, fracture fluid composition, closure pressure, frac fluid flowback, and the like.

With continued reference to FIG. 1, condition data 108 may include fluid properties. As used in the current disclosure, “fluid properties” refer to the characteristics and properties of the fracturing fluid used in the process. In one or more embodiments, fracturing fluid may include a mixture of water, sand (frac sand), and one or more chemicals that is pumped into the well at high pressure to create fractures in the underground rock formations, allowing for the extraction of natural gas or oil. The specific properties of the fracturing fluid play a crucial role in the effectiveness and safety of the fracking operation. Examples of fluid properties may include viscosity, density, friction reducers, proppant concentration, pH levels, Gel Breakers, biocides, and additives, and the like. Viscosity refers to the fluid's resistance to flow. In fracking, a fluid with the right viscosity is essential to effectively carry the proppant (sand) and distribute it into the fractures. The fluid should have sufficient viscosity to transport the proppant deep into the fractures and maintain its suspension but not be overly thick that it hinders pumping efficiency. The density of the fluid affects the pressure required to fracture the rock and the height to which the fractures extend. A fluid with the appropriate density helps create the desired fractures and prevents excessive fracturing that could extend beyond the target zone.

With continued reference to FIG. 1, processor 104 may be communicatively connected to one or more sensors 112. As used in this disclosure, a “sensor” is a device that is configured to detect a phenomenon and transmit information related to the detection of the phenomenon. For example, in some cases a sensor may transduce a detected phenomenon, such as without limitation, current, speed, direction, force, torque, moisture, temperature, pressure, geographic location, resistance, touch sensors, viscosity, fluid state, fluid density, and the like, into a sensed signal. Sensor 112 may include one or more sensors which may be the same, similar, or different. Sensor 112 may include one or more sensor suites with sensors in each sensor suite being the same, similar, or different. A sensor 112 may be located downhole. At least a sensor 112 may include a plurality of sensors. In an embodiment, sensor 112 may include a temperature sensor, accelerometer, gyro meter, pressure sensor, GPS, speed gauge, voltage sensors, current sensors, ohm sensors, touch sensors, viscosity sensor, motion sensor, density sensor, flow rate sensor, downhole gauge, electricity usage meter, multimeters, a carbon emissions sensor, natural gas sensor, image sensor, scale, materials sensor, micro seismic geophones, fiber optic sensors, radiation sensors, rotational sensors, venturi flow meters, and the like.

Still referring to FIG. 1, at least a sensor 112 may be used to produce measured reservoir conditions 116. As used in the current disclosure, a “measured reservoir condition” is an element of datum or data that reflects current reservoir conditions that is gathered using sensor 112. As used in the current disclosure, “reservoir conditions” refer to any event, occurrence, status, that occurs in the reservoir. Examples of reservoir conditions may include temperature, pressure, force, motion, and the like. Measured reservoir conditions 116 may be taken from wells that are similarly situated to the target well. As used in the current disclosure, the “target well” is a primary well that a prediction is being generated for using apparatus. Well may be similarly situated as a function of condition data 108, well geography, or other circumstances. In an embodiment, measured reservoir conditions 116 may include hydrostatic pressure, formation pressure, fracture pressure, bottomhole pressure, formation integrity test, equivalent circulating densities, differential pressure, bottomhole frac gradient, pressure transients, rate transients, and the like. Reservoir conditions may include reservoir pressure. As used in the current disclosure, “reservoir pressure” refers to the natural pressure existing within the underground rock formation (reservoir) that contains the trapped hydrocarbons (such as natural gas or oil). This pressure is an essential factor influencing the success and efficiency of the hydraulic fracturing process. Before fracking operations begin, engineers and geologists assess the reservoir pressure to understand the potential productivity of the well and the behavior of the hydrocarbons within the rock formation. Reservoir pressure is a critical parameter in the oil and gas industry as it significantly influences the behavior and production of hydrocarbons from a well. Reservoir pressure is typically measured in pounds per square inch (psi) or other pressure units. In some cases, reservoir pressure drives the flow of hydrocarbons from the reservoir into the wellbore and up to the surface. The pressure difference between the reservoir and the wellbore is the driving force that allows hydrocarbons to flow naturally or with the assistance of artificial lift methods. Reservoir pressure is critical in characterizing the reservoir and understanding its geology, connectivity, and fluid distribution. Pressure measurements are used to create pressure-depth profiles that help identify hydrocarbon-bearing zones. Monitoring changes in reservoir pressure over time is crucial for effective reservoir management. Declining reservoir pressure may indicate decreasing hydrocarbon reserves or the need for enhanced recovery techniques. During production, reservoir pressure tends to decline as hydrocarbons are extracted from the reservoir. As the fluids are depleted, the pressure in the reservoir decreases, and the production rate may decline unless managed effectively. In some cases, techniques like water or gas injection may be used to maintain or increase reservoir pressure, enhancing hydrocarbon recovery.

With continued reference to FIG. 1, processor 104 may be configured to generate expected reservoir conditions 120. As used in the current disclosure, “reservoir conditions” is an element of datum that reflects a prediction of reservoir conditions based on the condition datum. Processor 104 may generate expected reservoir conditions 120 in real time. This may mean the processor 104 computes the expected reservoir conditions 120 immediately as they occur, with minimal or no delay. Processor 104 may expected reservoir conditions 120 as function of the condition data 108 and historical versions of measured reservoir conditions 116. For example, this may include information regarding geological information, well logs, seismic data, petrophysical data, production history, and any available pressure data. In an embodiment, expected reservoir conditions 120 may use condition data 108 and historical versions of measured reservoir conditions 116 to build a detailed model of the reservoir. The generating the model may include creating a geological model that represents the subsurface structure, layering, and properties of the reservoir rock. Based on the condition data 108, historical versions of measured reservoir conditions 116, and the reservoir model, pressure-depth profiles may be created. These profiles may show how the reservoir pressure changes with depth within the reservoir. Processor 104 may model the fluid flow and pressure behavior within the reservoir over time. In some embodiments, processor 104 may predict the fluid flow and pressure behavior of the target well by dividing the reservoir into small grid cells and calculating the fluid properties and pressure distribution in each cell over time. The prediction may consider factors such as fluid flow, rock properties, boundary conditions, and well behavior.

With continued reference to FIG. 1, processor 104 may generate verification data 124 as a function of the measured reservoir conditions 116 and the expected reservoir conditions 120. As used in the current disclosure, “verification data” is information that conveys the accuracy of a predicted condition to the measured condition. A predicted condition is a condition that was inferred or generated using computing techniques or models, such as expected reservoir conditions 120, fracture network conditions 132, and reservoir geometry 136. Whereas a measured reservoir condition 116 is any condition that is generated using a sensor 112 to detect the current condition of a reservoir. The accuracy of the predicted conditions may be determined by comparing the measured conditions to the reservoir conditions. Verification data 124 may verify that processor 104 accurately predicts pressure events within the reservoir. This may include the timing, magnitude, and duration of each pressure event. Verification data 124 may be reflected as a percentage accuracy or numerical score. In some embodiments, a notification may be generated as a function of the verification data falling below a threshold. This notification may be presented as audio, visual, text, or haptic. The notification may be presented to the user on a user device such as a computing device, smartphone, tablet, laptop, smartwatch, and the like.

With continued reference to FIG. 1, processor 104 may be configured to convert condition data 108, measured reservoir conditions 116, expected reservoir conditions 120 using a machine-learning module, such as data conversion module, into a cleansed data format. As used in this disclosure, a “cleansed data format” is a format and/or structure for data where the data is transformed from an unprocessed format and/or structure into a processed format and/or structure that is prepared for use in the generation and training of an artificial intelligence (AI) model, for example a machine learning model, a neural network, and the like. Condition data 108 that is placed into a cleansed data format may be referred to as a cleansed condition data. Similarly, measured reservoir conditions 116 and expected reservoir conditions 120 that are placed in a cleansed data format may be referred to as cleansed measured reservoir conditions or cleansed reservoir conditions. A cleansed data format may be used to ensure data used for the generating and training of the AI model is relevant and accurate to generate an optimal AI model. A cleansed data format may also include data that is transformed by constructive transformation, destructive transformation, and/or structural transformation into the process format and/or structure. In some embodiments, constructive transformation of data may include adding data, replicating data, and the like. In some embodiments, destructive transformation of data may include fixing or removing incorrect, corrupted, incorrectly formatted, duplicate, or incomplete data within a dataset, and the like. In some embodiments, structural transformation of data may include moving and/or combining columns of data in a data set, and the like. The converting of data may include the processing, cleansing, standardizing, and categorizing of data into a cleansed data format for use in generating an accumulated artificial intelligence (AI) model. In an embodiment, the conversion of the condition data 108, the measured reservoir conditions 116, and expected reservoir conditions 120 may include the processing, cleansing, and standardizing of data into a data set and/or data bucket for use in generating an artificial intelligence model The conversion of data into a cleansed data format in the current disclosure may be consistent with the conversion of data into a cleansed data format disclosed in Non-provisional application Ser. No. 17/853,143 filed on Jun. 29, 2022, and entitled “APPARATUS AND METHOD FOR GENERATING A COMPILED ARTIFICIAL INTELLIGENCE (AI) MODEL,” and Non-provisional application Ser. No. 17/968,077 filed on Oct. 18, 2022, and entitled “AN APPARATUS AND METHOD FOR PREDICTING DOWNHOLE CONDITIONS,” both of which are incorporated herein by reference.

With continued reference to FIG. 1, processor 104 may be configured to identify a flagged data 128 as a function of the expected reservoir conditions 120. As used in the current disclosure, “flagged data” is an element of data used to highlight pressure events within the reservoir. A “pressure event,” as used in the current disclosure, refers to a significant and sudden change in the pressure conditions within the reservoir. These events can have various causes and consequences, and they are of great interest and concern to reservoir engineers and operators as they can impact reservoir behavior and production. Pressure events may include positive pressure events and negative pressure events. Positive pressure events occur when the reservoir pressure increases abruptly or unexpectedly. Positive pressure events may be caused by injection operations, fluid expansion, gas cap expansion, injection operations, and like. Negative pressure events occur when the reservoir pressure decreases suddenly or unexpectedly. Negative pressure events may be caused by fluid withdrawal, fluid migration, reservoir compaction, and the like. Flagged data 128 may additionally be used to highlight abnormal conditions, mark the beginning or the end of a pressure cycle, or any other points of interest that occur within the reservoir. Flagged data 128 may be generated from wells that are similarly situated to the target well as a function of condition data 108, this will be discussed in greater detail herein below. Flagged data 128 may be generated in real time or shortly before the prediction of a pressure event as shown by the reservoir conditions. Flagged data 128 may additionally include historical flagged data. As used in the current disclosure, “historical flagged data” is a flagged data 128 that was recorded prior to the prediction of expected reservoir conditions 120. Historical flagged data may be recorded several days, months, or years prior to the current prediction of expected reservoir conditions 120.

With continued reference to FIG. 1, flagged data 128 may include marking a segment of the expected reservoir conditions 120. A segment may comprise a portion of expected reservoir conditions 120 over a predetermined period of time. Flagged data 128 may highlight when a well is experiencing high/low temperature, pressure, viscosity, changes in pressure, changes in rate, or density of the output of the well. Flagged data 128 may include historical flagged data from the current well or flagged data 128 from a second well that is similarly situated to the target well as a function of condition data 108. Wells that are similarly situated to the current well may include wells that are geographically similar by ground conditions to the current well or wells that are in the same or similar geographic region or area. Similarly situated wells may also comprise wells that share similar construction features, current operation datum, and/or system geometry.

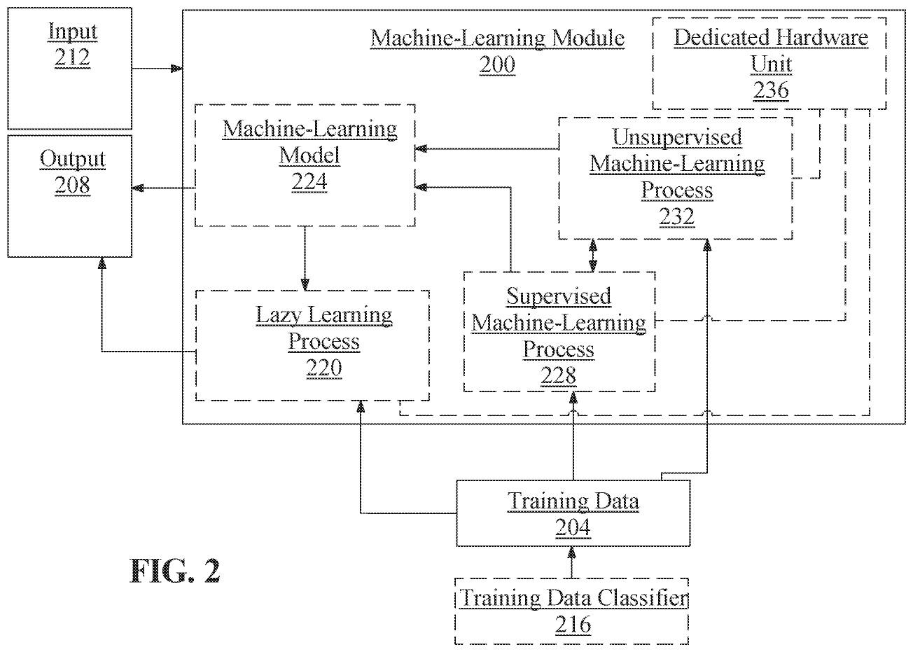

With continued reference to FIG. 1, processor 104 may generate flagged data 128 using a flag data classifier. As used in the current disclosure, a “flag data classifier” is a machine-learning model that is configured to generate flagged data 128. Flag data classifier may be consistent with the classifier as described below in FIG. 2. Inputs to the flag data classifier may include condition data 108, measured reservoir data 116, verification data 124, expected reservoir conditions 120, examples of flagged data 128, cleansed versions of the data, and the like. Outputs to the flag data classifier may include flagged data 128 tailored to the expected reservoir conditions 120. flag training data may include a plurality of data entries containing a plurality of inputs that are correlated to a plurality of outputs for training a processor by a machine-learning process. In an embodiment, flag training data may include a plurality of expected reservoir conditions 120 correlated to examples of flagged data 128. flag training data may be received from database 300. flag training data may contain information about condition data 108, measured reservoir data 116, verification data 124, expected reservoir conditions 120, examples of flagged data 128, and the like. In an embodiment, flag training data may be iteratively updated as a function of the input and output results of past flag data classifier or any other machine-learning model mentioned throughout this disclosure. The machine-learning model may be performed using, without limitation, linear machine-learning models such as without limitation logistic regression and/or naive Bayes machine-learning models, nearest neighbor machine-learning models such as k-nearest neighbors machine-learning models, support vector machines, least squares support vector machines, fisher's linear discriminant, quadratic machine-learning models, decision trees, boosted trees, random forest machine-learning model, and the like.

With continued reference FIG. 1, the flagged data 128 may be identified and sorted using a flag data classifier. A Flagged data classifier may be configured to categorize flagged data 128. Categories may include normal reading, abnormal reading, high/low pressure readings, high/low temperature readings, high/low viscosity readings, geographic conditions, well conditions, and the like. A Flagged data classifier may be trained using flag training data. Flag training data may include flagged data 128, a plurality of categories, downhole conditions 116, and the like. Flagged training data may be configured to correlate flagged data 128 to a category of the plurality of categories. Flagged data classifier may include a K-nearest neighbors (KNN) algorithm, discussed in greater detail herein below.

With continued reference to FIG. 1, processor 104 may generate a reservoir model to determine the fracture network conditions 132 and the reservoir geometry 136. As used in the current disclosure, a “reservoir model” is a mathematical and computational representation of the reservoir of the target well. The reservoir model is a tool that may advance a user's understanding of the subsurface geology, fluid flow behavior, and predicting reservoir performance during exploration, development, and production phases. The reservoir model may integrate various data sources and geological information to create a comprehensive depiction of the reservoir's physical properties such as fracture network conditions 132 and reservoir geometry 136. A reservoir model 132 may provide a geological representation of the subsurface. This may include information about the rock layers, stratigraphy, fault systems, and other structural features that make up the reservoir. Inputs into the reservoir model may include condition data 108, expected reservoir conditions 120, and flagged data 128. Outputs to the reservoir model may include the fracture network conditions 132 and the reservoir geometry 136. In some cases, outputs to the reservoir model may be displayed graphically, this may include both 2D and 3D graphs. The reservoir model may determine the fracture network conditions 132 and the reservoir geometry 136 by constructing a geological framework for the reservoir. This may involve creating a 3D representation of the subsurface structure, including layering, faults, and other geological features. Geological representation may be based on seismic data, well logs, geophysical information, along with other inputs to the reservoir model. The reservoir model may partition the reservoir using a grid system of interconnected cells or blocks. Each grid cell represents a small volume of the reservoir rock and contains data on rock properties, such as porosity, permeability, and lithology. The grid can be structured (e.g., Cartesian) or unstructured, depending on the complexity of the reservoir. Reservoir properties, such as fracture network conditions 132 and the reservoir geometry 136, are assigned to each grid cell based on the available data. Geostatistical methods are often used to interpolate properties between well control points to create a continuous model. The reservoir model also incorporates information about fluid distribution, such as oil, gas, and water saturation. These fluid properties are critical in understanding the reservoir's hydrocarbon potential and the likely behavior during production. In an embodiment, reservoir model may be configured to simulate reservoir conditions or fracture network conditions in a manner described in Non-provisional application Ser. No. 17/986,474 filed on Nov. 14, 2022 and entitled “AN APPARATUS AND METHOD FOR MULTI-STAGE FRACKING,” the entirety of which is incorporated herein by reference.

With continued reference to FIG. 1, processor 104 may be configured to determine fracture network conditions 132 as a function of the flagged data 128. As used in the current disclosure, “fracture network conditions” may refer to the characteristics of the system of interconnected fractures created within the reservoir rock during the hydraulic fracturing (i.e. fracking) process. In one or more embodiments, fracture network conditions may include a summation of a plurality of fracture geometries of reservoir geometry. Hydraulic fracturing involves injecting a high-pressure fluid mixture (e.g., water, sand, and chemicals) into the wellbore to create fractures in the underground rock formation, typically shale or other tight formations. The primary objective of creating a fracture network is to enhance the flow of hydrocarbons, such as natural gas or oil, from the reservoir to the wellbore for extraction. Fracture network conditions 132 may include information regarding fracture density, fracture length, fracture complexity, fracture width, fracture orientation, fracture spacing, and the like. In a non-limiting example, fracture density refers to the number of fractures created per unit volume of rock. A higher fracture density means that more fractures are generated, providing more pathways for hydrocarbons to flow to the wellbore. Fracture length may be the extent to which the created fractures propagate away from the wellbore. Longer fractures extend deeper into the reservoir, increasing the contact area with the hydrocarbons and enhancing production. Fracture complexity may describe the shape and branching of the fractures. A more complex fracture network has multiple branches and interconnected fractures, which improves the connectivity of the pathways for hydrocarbons. Fracture width may refer to the extent of opening or aperture of the fractures. A wider fracture provides more space for the proppant (usually sand) to hold the fractures open, thereby enhancing the conductivity and allowing hydrocarbons to flow more easily. Fracture orientation may refer to the direction in which the fractures are created relative to the natural stress regime of the reservoir. Fractures are ideally oriented to intersect the maximum horizontal stress direction to promote better fracture propagation. Fracture spacing may refer to the distance between individual fractures in the network. Optimal fracture spacing ensures adequate coverage of the reservoir, maximizing hydrocarbon drainage. During hydraulic fracturing, proppants (typically sand) are mixed with the fracturing fluid and injected into the fractures. Proper proppant placement is essential to keep the fractures open after the pressure is reduced, allowing hydrocarbons to flow through the network. Reservoir models often have very high-resolution grids with millions of cells. In some cases, to make the simulations more manageable, the model may undergo a process called “upscaling” to aggregate smaller cells into larger representative cells. After building the reservoir model, it is validated against real-world data, such as well test results and production data. This step ensures that the model accurately reflects the actual reservoir behavior.

With continued reference to FIG. 1, fracture network conditions 132 may be calculated as a function of the fracture network conditions of a parent well. As used in the current disclosure, a “parent well” refers to the initial or primary well that is drilled into subsurface rock formations. Parent wells may be drilled vertically or at a slight angle to access the targeted reservoir. In an embodiment, fracture network conditions 132 of a parent well may be determined prior to the drilling or fracking activity on the target well. The parent well may have previously undergone the fracking process. In some cases, the parent well and the target well may have a parent well and child well relationship. As used in the current disclosure, a “child well” refers to a well that is drilled in close proximity to an existing or parent well. In some embodiments, child well may include a secondary well where the parent well includes the primary well. The parent well is typically the initial well drilled in a specific location to access a subsurface reservoir. The child well may be created to maximize the recovery of resources from the same reservoir or adjacent sections of the reservoir. This relationship is also known as “well spacing” or “well development strategy” and involves drilling multiple wells in a coordinated manner to optimize the recovery of hydrocarbons from a specific subsurface reservoir. After the parent well has been established and is in production, additional wells, known as child wells or offset wells, may be drilled from the same well pad. Child wells may be strategically spaced near the parent well to maximize the recovery of hydrocarbons from the same or adjacent rock formations. The spacing between parent and child wells is determined based on geological and engineering considerations. In some cases, the child wells tap into the same reservoir or neighboring sections of the reservoir that the parent well accesses. This allows for the efficient extraction of oil or natural gas from the reservoir. In some cases, one or both of the parent well and the child well may undergo their own hydraulic fracturing operations to further enhance production. Fracturing operations on the child well may be conducted independently of the parent well.

With continued reference to FIG. 1, processor 104 may be configured to predict reservoir geometry 136. As used in the current disclosure, a “reservoir geometry” refers to the physical shape, size, fracture geometry, and structural characteristics of an underground rock formation (reservoir) that contains hydrocarbons, such as oil or natural gas. Reservoir geometries 136 may be described as the total volume of oil or gas within the reservoir. Processor 104 may predict the reservoir geometry 136 in real time. As used in the current disclosure, “Real-time” refers to the capability of a system to process and respond to events or inputs immediately as they occur, with minimal or no delay. Real-time systems must meet specific timing constraints and deadlines to ensure that their responses are timely and predictable. The real-time prediction of reservoir geometry 136 may be generated as a function of the expected reservoir conditions 120 and the flagged data 128 associated with this reservoir conditions. Reservoir geometry 136 may be important when determining the productivity, recoverability, and overall performance of a reservoir. Reservoir geometry 136 may describe the overall shape and size of the subsurface rock formation. Reservoirs can have various shapes, such as cylindrical, elongated, or irregular. The size of a reservoir can range from small and localized to vast and extensive. Many reservoirs are composed of multiple layers of different rock types and formations. These layers, known as stratification, have varying properties and thicknesses. The layering can significantly impact fluid flow and hydrocarbon distribution within the reservoir. Reservoir geometry 136 may be closely linked to the porosity and permeability characteristics of the rock formations. Porosity refers to the percentage of pore space within the rock that can hold fluids like oil and gas. Permeability refers to the ability of the rock to allow fluids to flow through it. These properties influence how easily hydrocarbons can move within the reservoir and be recovered. Reservoir geometry 136 may include defining the shape and orientation of hydrocarbon traps. Hydrocarbon traps are geological configurations that prevent hydrocarbons from migrating further and lead to their accumulation in economic quantities. Reservoir geometry 136 may include various geological structures, such as faults and folds, which can affect the reservoir's behavior. Faults are fractures where there has been movement of the rock on either side, while folds are bends or flexures in the rock layers. Anticlines and synclines are specific types of geological folds. An anticline is an upward-arching fold, where the oldest rock layers are in the center, while a syncline is a downward-folding with the youngest layers in the center. These structural features can create traps for hydrocarbons, enhancing reservoir potential.

With continued reference to FIG. 1, processor 104 may display reservoir geometry 136 in various manners. Reservoir geometry 104 may represent the complex subsurface structures and reservoir properties in a visual and interactive manner, allowing users, such as geologists, reservoir engineers, and other stakeholders, to understand the reservoir's geometry better. Reservoir geometries 136 may be represented as a three-dimensional (3D) representation of the target well. As used in the current disclosure, a “three-dimensional representation” of a reservoir is a visual depiction of the subsurface rock formations and fluid distribution within an oil or gas reservoir. A three-dimensional representation of the target well may include depicting the target well along a set of Cartesian coordinates, this may include an XYZ axis. In some cases, reservoir geometries 136 may be represented in three dimensions (3D). Processor 104 may allow users to visualize the subsurface rock formations and fluid distributions as 3D models. This provides a comprehensive view of the reservoir's shape, size, layering, and structural features. In an embodiment, Reservoir geometries 136 may be displayed as cross-sections and slices of the reservoir. These are 2D representations of specific planes or cuts through the 3D reservoir model, allowing users to examine specific features of the reservoir in detail. Reservoir geometry 104 may include isosurfaces that represent specific reservoir properties, such as porosity or fluid saturation. They help highlight regions with particular values of interest within the reservoir. Reservoir geometry 136 include a method for the visualization of subsurface properties in a semi-transparent manner. This allows users to see the distribution of properties throughout the entire volume of the reservoir. In some cases, geological maps may be display over the top of the reservoir geometry 136. Geological maps display the surface expression of subsurface structures and reservoir boundaries. They can be overlaid on top of satellite imagery or topographic maps to provide context.

With continued reference to FIG. 1, processor 104 may be configured to predict reservoir geometry 136 as a function of flagged data 128. The pressure events denoted by flagged data 128 may be simulated using a reservoir model. Information regarding the pressure event, such as its magnitude, duration, and location within the reservoir are all integrated into the reservoir model. Processor 104 may solve the governing equations of fluid flow and mass conservation in porous media, and the like when calculating reservoir geometry 136. The most common approach is based on numerical methods, such as finite difference or finite element methods. The reservoir model software performs a dynamic simulation of the reservoir, considering the pressure event's influence on fluid flow and fluid-rock interactions. The reservoir model accounts for fluid compressibility, rock deformations, and changes in fluid properties due to the pressure event. The simulation may produce reservoir geometry 136. The reservoir model may include a dynamic simulation of the reservoir, considering the pressure event's influence on fluid flow and fluid-rock interactions. The reservoir model accounts for fluid compressibility, rock deformations, and changes in fluid properties due to the pressure event. The processor 104 may perform stress analysis to evaluate how the pressure event affects the in-situ stress conditions within the reservoir. Changes in stress conditions can impact fracture propagation and reservoir behavior. If the pressure event is significant enough to create new fractures or affect existing fractures, the processor 104 may simulate fracture propagation within the reservoir models. As the simulation progresses, the processor 104 continuously updates the reservoir geometry based on the changes caused by the pressure event. This may include the creation of new fractures, alterations in reservoir boundaries, and changes in the extent of reservoir layers.

With continued reference to FIG. 1, processor 104 may generate reservoir geometry 136 using a reservoir machine-learning model 136. As used in the current disclosure, a “reservoir machine-learning model” is a machine-learning model that is configured to generate fracture network conditions 132 and the reservoir geometry 136. Reservoir machine machine-learning model may be consistent with the machine-learning model described below in FIG. 2. Inputs to the reservoir machine-learning model 136 may include condition data 108, measured reservoir data 116, verification data 124, expected reservoir conditions 120, flagged data 128, cleansed versions of the data, examples of reservoir geometry 136, examples of fracture network conditions 132, and the like. Outputs to the reservoir machine-learning model 136 may include reservoir geometry 136 or fracture network conditions 132 tailored to the flagged data 128. In some cases, reservoir machine-learning model 136 may be configured to generate a reservoir model to determine the fracture network conditions 132 and the reservoir geometry 136. Reservoir training data may include a plurality of data entries containing a plurality of inputs that are correlated to a plurality of outputs for training a processor by a machine-learning process. In an embodiment, reservoir training data may include a plurality of flagged data 128 correlated to examples of reservoir geometry 136. In another embodiment, reservoir training data may include a plurality of flagged data 128 correlated to examples of fracture network conditions 132. Reservoir training data may be received from database 300. Reservoir training data may contain information about condition data 108, measured reservoir data 116, verification data 124, expected reservoir conditions 120, flagged data 128, cleansed versions of the data, examples of reservoir geometry 136, examples of fracture network conditions 132, and the like. In an embodiment, reservoir training data may be iteratively updated as a function of the input and output results of past reservoir machine-learning model 136 or any other machine-learning model mentioned throughout this disclosure. The machine-learning model may be performed using, without limitation, linear machine-learning models such as without limitation logistic regression and/or naive Bayes machine-learning models, nearest neighbor machine-learning models such as k-nearest neighbors machine-learning models, support vector machines, least squares support vector machines, fisher's linear discriminant, quadratic machine-learning models, decision trees, boosted trees, random forest machine-learning model, and the like.

With continued reference to FIG. 1, machine learning plays a crucial role in enhancing the function of software for predicting a reservoir geometry 136, specifically in identifying patterns of within pressure events that lead to changes in reservoir geometry 136. By analyzing vast amounts of data related to judicial data, machine learning algorithms can identify patterns, correlations, and dependencies that contribute to a pattern of changes in reservoir geometry 136 during one or more pressure events. These algorithms can extract valuable insights from various sources, including well logs, previous pressure events, reservoir geometry 136 of similarly situated wells. By applying machine learning techniques, the software can predict reservoir geometry 136 extremely accurately. Machine learning models may enable the software to learn from past collaborative experiences of the entities and iteratively improve its training data over time. By leveraging historical data, the machine learning model can recognize patterns of unfair, unethical, or illegal treatment that have negative effects on the on the outcomes of criminal cases. This iterative learning process empowers the software to continuously refine its understanding of the dynamics of the judicial system and generate more accurate and actionable set of correction factors 124.

With continued reference to FIG. 1, processor 104 may be configured to update the training data of the reservoir machine-learning model 136 using user inputs. A reservoir machine-learning model 136 may use user input to update its training data, thereby improving its performance and accuracy. In embodiments, the reservoir machine-learning model 136 may be iteratively updated using input and output results of the reservoir machine-learning model 136. The reservoir machine-learning model 136 may then be iteratively retrained using the updated machine-learning model 136. For instance, and without limitation, first reservoir machine-learning model may be trained using first training data from, for example, and without limitation, training data from a user input or database. The reservoir machine-learning model may then be updated by using previous inputs and outputs from the first reservoir machine-learning model as second training data to then train a second machine learning model. This process of updating the reservoir machine learning model may be continuously done to create subsequent reservoir machine-learning models to improve the speed and accuracy of reservoir machine-learning model. When users interact with the software, their actions, preferences, and feedback provide valuable information that can be used to refine and enhance the model. This user input is collected and incorporated into the training data, allowing the machine learning model to learn from real-world interactions and adapt its predictions accordingly. By continually incorporating user input, the model becomes more responsive to user needs and preferences, capturing evolving trends and patterns. This iterative process of updating the training data with user input enables the machine learning model to deliver more personalized and relevant results, ultimately enhancing the overall user experience.

Incorporating the user feedback may include updating the training data by removing or adding correlations of user data to a path or resources as indicated by the feedback. Any machine-learning model as described herein may have the training data updated based on such feedback or data gathered using a web crawler as described above. For example, correlations in training data may be based on outdated information wherein, a web crawler may update such correlations based on more recent resources and information.

With continued reference to FIG. 1, processor 104 may use user feedback to train the machine-learning models and/or classifiers described above. For example, classifier may be trained using past inputs and outputs of classifier. In some embodiments, if user feedback indicates that an output of classifier was “bad,” then that output and the corresponding input may be removed from training data used to train classifier, and/or may be replaced with a value entered by, e.g., another value that represents an ideal output given the input the machine learning model originally received, permitting use in retraining, and adding to training data; in either case, classifier may be retrained with modified training data as described in further detail below. In some embodiments, training data of classifier may include user feedback.

With continued reference to FIG. 1, in some embodiments, an accuracy score may be calculated for classifier using user feedback. For the purposes of this disclosure, “accuracy score,” is a numerical value concerning the accuracy of a machine-learning model. For example, the accuracy of a reservoir geometry 136 may be averaged to determine an accuracy score. In some embodiments, an accuracy score may be determined for pairing of entities. Accuracy score or another score as described above may indicate a degree of retraining needed for a machine-learning model such as a classifier; processor 104 may perform a larger number of retraining cycles for a higher number (or lower number, depending on a numerical interpretation used), and/or may collect more training data for such retraining.

Still referring to FIG. 1, the processor may be configured to generate a machine-learning model, such as reservoir machine-learning model 140, using a Naive Bayes classification algorithm. Naive Bayes classification algorithm generates classifiers by assigning class labels to problem instances, represented as vectors of element values. Class labels are drawn from a finite set. Naive Bayes classification algorithm may include generating a family of algorithms that assume that the value of a particular element is independent of the value of any other element, given a class variable. Naive Bayes classification algorithm may be based on Bayes Theorem expressed as P(A/B)=P(B/A) P(A)÷P(B), where P(A/B) is the probability of hypothesis A given data B also known as posterior probability; P(B/A) is the probability of data B given that the hypothesis A was true; P(A) is the probability of hypothesis A being true regardless of data also known as prior probability of A; and P(B) is the probability of the data regardless of the hypothesis. A naive Bayes algorithm may be generated by first transforming training data into a frequency table. processor 104 may then calculate a likelihood table by calculating probabilities of different data entries and classification labels. processor 104 may utilize a naive Bayes equation to calculate a posterior probability for each class. A class containing the highest posterior probability is the outcome of prediction. Naive Bayes classification algorithm may include a gaussian model that follows a normal distribution. Naive Bayes classification algorithm may include a multinomial model that is used for discrete counts. Naive Bayes classification algorithm may include a Bernoulli model that may be utilized when vectors are binary.

Still referring to FIG. 1, processor 104 may be configured to generate a machine-learning model, such as a reservoir machine-learning model 136, using a K-nearest neighbors (KNN) algorithm. A “K-nearest neighbors algorithm” as used in this disclosure, includes a classification method that utilizes feature similarity to analyze how closely out-of-sample-features resemble training data to classify input data to one or more clusters and/or categories of features as represented in training data; this may be performed by representing both training data and input data in vector forms, and using one or more measures of vector similarity to identify classifications within training data, and to determine a classification of input data. K-nearest neighbors algorithm may include specifying a K-value, or a number directing the classifier to select the k most similar entries training data to a given sample, determining the most common classifier of the entries in the database, and classifying the known sample; this may be performed recursively and/or iteratively to generate a classifier that may be used to classify input data as further samples. For instance, an initial set of samples may be performed to cover an initial heuristic and/or “first guess” at an output and/or relationship, which may be seeded, without limitation, using expert input received according to any process as described herein. As a non-limiting example, an initial heuristic may include a ranking of associations between inputs and elements of training data. Heuristic may include selecting some number of highest-ranking associations and/or training data elements.

With continued reference to FIG. 1, generating k-nearest neighbors algorithm may generate a first vector output containing a data entry cluster, generating a second vector output containing an input data, and calculate the distance between the first vector output and the second vector output using any suitable norm such as cosine similarity, Euclidean distance measurement, or the like. Each vector output may be represented, without limitation, as an n-tuple of values, where n is at least two values. Each value of n-tuple of values may represent a measurement or other quantitative value associated with a given category of data, or attribute, examples of which are provided in further detail below; a vector may be represented, without limitation, in n-dimensional space using an axis per category of value represented in n-tuple of values, such that a vector has a geometric direction characterizing the relative quantities of attributes in the n-tuple as compared to each other. Two vectors may be considered equivalent where their directions, and/or the relative quantities of values within each vector as compared to each other, are the same; thus, as a non-limiting example, a vector represented as [5, 10, 15] may be treated as equivalent, for purposes of this disclosure, as a vector represented as [1, 2, 3]. Vectors may be more similar where their directions are more similar, and more different where their directions are more divergent; however, vector similarity may alternatively or additionally be determined using averages of similarities between like attributes, or any other measure of similarity suitable for any n-tuple of values, or aggregation of numerical similarity measures for the purposes of loss functions as described in further detail below. Any vectors as described herein may be scaled, such that each vector represents each attribute along an equivalent scale of values. Each vector may be “normalized,” or divided by a “length” attribute, such as a length attribute l as derived using a Pythagorean norm l=\sqrt{Σᵢ₌₀ⁿaᵢ²}, where aᵢ is attribute number experience of the vector. Scaling and/or normalization may function to make vector comparison independent of absolute quantities of attributes, while preserving any dependency on the similarity of attributes; this may, for instance, be advantageous where cases represented in training data are represented by different quantities of samples, which may result in proportionally equivalent vectors with divergent values.

With continued reference to FIG. 1, processor 104 may be configured to generate a pressure report as a function of the reservoir geometry 136. As used in the current disclosure, a “pressure report” is a report detailing the hydraulic fracturing pressures as the reservoir geometry changes. A pressure report may be generated in real time as the reservoir geometry and the frac geometry change. A pressure report may provide details of how fractures are forming and propagating. The pressure behavior may provide analysis into the mechanical properties of the rock, stress distribution, and the effectiveness of the fracturing fluid in creating and maintaining fractures. In some embodiments, a pressure report may be generated as a function of the flagged data 128. In that case processor 104 may use data generated by the pressure report to calculate the geometry and length of the fractures created. This information is crucial for optimizing production strategies and maximizing hydrocarbon recovery. A pressure report may also include an analysis of the pressure decline after the fracturing. This report may contain analysis of how and when fractures are closing, and the well is transitioning from injection to production. It also may provide information on the effectiveness of proppant placement, which is the material injected to keep the fractures open. A pressure report may also contain details of how the pressure works after the fracturing treatment is completed. Professor 104 may analyze the flagged data 128 to assess the success of the treatment and make any necessary adjustments for future operations. This analysis may also be used to generate reservoir management recommendations 140 regarding potential refracturing or other well interventions. In other embodiments, a pressure report may contain information about ensuring well integrity and safety. Excessive pressures or unexpected pressure behavior can lead to wellbore failures or other issues that might compromise the well's performance and environmental protection.

With continued reference to FIG. 1, processor 104 may be configured to generate reservoir management recommendations 140 as a function of the reservoir geometry 136. As used in the current disclosure, a “reservoir management recommendations” is one or more suggestion to a user on how to manage the reservoir. Based on the real-time simulations and visualizations, the processor 104 may provide reservoir management recommendations 140 to optimize well performance and manage reservoir behavior effectively. These recommendations could include adjusting well completion design, modifying injection rates, or implementing reservoir management techniques. Reservoir management recommendations 140 may be specific strategies and actions suggested to a user to optimize the production and recovery of hydrocarbons from an oil or gas reservoir. These recommendations may be based on a comprehensive understanding of the reservoir's behavior, performance data, and economic factors. The goal of a reservoir management recommendations 140 is to maximize hydrocarbon recovery while ensuring operational efficiency and long-term sustainability. Examples of reservoir management recommendations 140 may include well placement, injection strategies, pressure management, reservoir surveillance, integrated asset modeling, water and gas handling, risk assessment and mitigation, and the like. Reservoir management recommendations 140 may involve adjusting well production rates, optimizing choke settings, and managing artificial lift systems to achieve the highest possible hydrocarbon production while maintaining well integrity. Additionally, Reservoir management recommendations 140 may include adjusting injection rates, patterns, and well locations for pressure maintenance or enhanced oil recovery (EOR) purposes. reservoir management recommendations 140 include suggestions prompting the user to adhere to environmental regulations and ensuring responsible operations to minimize the impact on the environment and surrounding communities.

Most north American drilling is not ‘Green Field’, it is now ‘brown field’ which means most wells being drilled and fracked are being done so in non-virgin reservoirs. Meaning the risk of interaction with parent wells/secondary wells are high. In some embodiments, the current invention can be used to predict when the frac growth from the treatment well is going to interfere or contact a nearby well. Additionally the invention may be used to provide operators with data driven suggestions of when the shut off of that frac zone, stopping it from further growth toward the parent wells/secondary wells.

Still referring to FIG. 1, processor 104 may generate a fracture network management recommendation as a function of the fracture network conditions 132. As used in the current disclosure, a “fracture network management recommendation” is one or more suggestion to a user on how to manage a fracture network of one or more wells. A fracture network management suggestion may be directed at the target well or a secondary well. Meaning the suggestions provided by processor 104 may be used to manage the fracture network interactions between a parent well and a child well, or a target well and a secondary well, respectively. In another embodiment, fracture network management suggestions may be used to make recommendations of the placement, size, angle, geometry, and the like of a child well. Based on the reservoir model and visualizations, the processor 104 may provide fracture network recommendations to manage the fracture network effectively. A fracture network management recommendation may include a suggestion to implement a sequential fracturing approach, starting with the innermost fractures and progressing outward. This allows for better reservoir pressure management and improved hydrocarbon recovery. A fracture network management recommendation may also include a suggestion to use a higher concentration of proppant (e.g., sand) in the hydraulic fracturing fluid to prop open fractures and maintain permeability. Conduct lab tests to determine the most suitable proppant type. Fracture network management recommendation may include the implementation a pressure maintenance plan, such as water or gas injection, to maintain reservoir pressure and extend the productive life of the wells. Additional suggestions of a fracture network management recommendation may include suggestions related to well spacing and placement, injection rate control, refracturing strategy, fluid selection and viscosity control, pressure maintenance strategy, environmental mitigation measures, economic optimization, risk mitigation, reservoir pressure management, and the like. In an embodiment, a fracture network management recommendation may include

Still referring to FIG. 1, processor 104 may generate a fracture network management recommendation and/or a reservoir management recommendations 140 using a management machine learning model. As used in the current disclosure, a “management machine machine-learning model” is a machine-learning model that is configured to generate a fracture network management recommendation and/or a reservoir management recommendations 140. A management machine-learning model may be consistent with the machine-learning model described below in FIG. 2. Inputs to the management machine machine-learning model may include condition data 108, measured reservoir data 116, verification data 124, expected reservoir conditions 120, flagged data 128, cleansed versions of the data, examples of reservoir geometry 136, fracture network conditions 132, parent well fracture network conditions, pressure reports, examples of a fracture network management recommendation, examples of a reservoir management recommendations 140, and the like. Outputs to the management machine-learning model may include reservoir management recommendations 140 based on the reservoir geometry. Outputs the management machine-learning model may include a fracture network management recommendation tailored to the fracture network conditions. Management training data may include a plurality of data entries containing a plurality of inputs that are correlated to a plurality of outputs for training a processor by a machine-learning process. In an embodiment, management training data may include a plurality of reservoir geometries correlated to examples of reservoir management recommendations 140. In an embodiment, management training data may include a plurality of fracture network conditions correlated to examples of fracture network management recommendations. Management training data may be received from database 300. Management training data may contain information about condition data 108, measured reservoir data 116, verification data 124, expected reservoir conditions 120, flagged data 128, cleansed versions of the data, examples of reservoir geometry 136, fracture network conditions 132, parent well fracture network conditions, pressure reports, examples of a fracture network management recommendation, examples of a reservoir management recommendations 140, and the like. In an embodiment, management training data may be iteratively updated as a function of the input and output results of past management machine machine-learning model or any other machine-learning model mentioned throughout this disclosure. The machine-learning model may be performed using, without limitation, linear machine-learning models such as without limitation logistic regression and/or naive Bayes machine-learning models, nearest neighbor machine-learning models such as k-nearest neighbors machine-learning models, support vector machines, least squares support vector machines, fisher's linear discriminant, quadratic machine-learning models, decision trees, boosted trees, random forest machine-learning model, and the like.

Still referring to FIG. 1, processor 104 may be configured to display a reservoir geometry 136 using a display device 144. As used in the current disclosure, a “display device” is a device that is used to display a plurality of data and other digital content. A display device 144 may include a user interface. A “user interface,” as used herein, is a means by which a user and a computer system interact; for example through the use of input devices and software. A user interface may include a graphical user interface (GUI), command line interface (CLI), menu-driven user interface, touch user interface, voice user interface (VUI), form-based user interface, any combination thereof, and the like. A user interface may include a smartphone, smart tablet, desktop, or laptop operated by the user. In an embodiment, the user interface may include a graphical user interface. A “graphical user interface (GUI),” as used herein, is a graphical form of user interface that allows users to interact with electronic devices. In some embodiments, GUI may include icons, menus, other visual indicators, or representations (graphics), audio indicators such as primary notation, and display information and related user controls. A menu may contain a list of choices and may allow users to select one from them. A menu bar may be displayed horizontally across the screen such as pull-down menu. When any option is clicked in this menu, then the pulldown menu may appear. A menu may include a context menu that appears only when the user performs a specific action. An example of this is pressing the right mouse button. When this is done, a menu may appear under the cursor. Files, programs, web pages and the like may be represented using a small picture in a graphical user interface. For example, links to decentralized platforms as described in this disclosure may be incorporated using icons. Using an icon may be a fast way to open documents, run programs etc. because clicking on them yields instant access. Information contained in user interface may be directly influenced using graphical control elements such as widgets. A “widget,” as used herein, is a user control element that allows a user to control and change the appearance of elements in the user interface. In this context a widget may refer to a generic GUI element such as a check box, button, or scroll bar to an instance of that element, or to a customized collection of such elements used for a specific function or application (such as a dialog box for users to customize their computer screen appearances). User interface controls may include software components that a user interacts with through direct manipulation to read or edit information displayed through user interface. Widgets may be used to display lists of related items, navigate the system using links, tabs, and manipulate data using check boxes, radio boxes, and the like.

With continued to FIG. 1, processor 104 may be configured to predict secondary well conditions as a function of the fracture network conditions 132. As used in the current disclosure, “secondary well conditions” are conditions associated with a secondary well. A secondary well may be any well that is not the target well. In some cases, a secondary well maybe a parent well or a child well. For instance, and without limitation, a secondary well may include a child well, as previously discussed in this disclosure. A secondary well may be a well that is geographically near or proximate the target well. In some embodiments, secondary well may include a well that is connected to the same reservoir as the target well. Secondary well conditions may include any conditions described within this disclosure. This may include secondary well pressure, fracture network conditions of the secondary well, along with other various downhole and non-downhole conditions. In an embodiment, secondary well conditions may include one or more predictions of how fracking or drilling in the target well may affect the secondary well. In a non-limiting example, secondary well conditions may include a determination of whether the fracture network conditions 132 will affect drilling operations in the secondary well. This may include a determination if the fracture network of the target well will intersect the fracture network of one or more secondary wells. Secondary well conditions may additionally include a determination of whether fracking and/or drilling can safely occur simultaneously within the target well and the secondary well. In an embodiment, a model or simulation, such as the reservoir model, may be used to simulate how the fracture network conditions 132 of the target well will affect the secondary well.

Referring now to FIG. 2, an exemplary embodiment of a machine-learning module 200 that may perform one or more machine-learning processes as described in this disclosure is illustrated. Machine-learning module may perform determinations, classification, and/or analysis steps, methods, processes, or the like as described in this disclosure using machine learning processes. A “machine learning process,” as used in this disclosure, is a process that automatedly uses training data 204 to generate an algorithm instantiated in hardware or software logic, data structures, and/or functions that will be performed by a computing device/module to produce outputs 208 given data provided as inputs 212; this is in contrast to a non-machine learning software program where the commands to be executed are determined in advance by a user and written in a programming language.

Still referring to FIG. 2, “training data,” as used herein, is data containing correlations that a machine-learning process may use to model relationships between two or more categories of data elements. For instance, and without limitation, training data 204 may include a plurality of data entries, also known as “training examples,” each entry representing a set of data elements that were recorded, received, and/or generated together; data elements may be correlated by shared existence in a given data entry, by proximity in a given data entry, or the like. Multiple data entries in training data 204 may evince one or more trends in correlations between categories of data elements; for instance, and without limitation, a higher value of a first data element belonging to a first category of data element may tend to correlate to a higher value of a second data element belonging to a second category of data element, indicating a possible proportional or other mathematical relationship linking values belonging to the two categories. Multiple categories of data elements may be related in training data 204 according to various correlations; correlations may indicate causative and/or predictive links between categories of data elements, which may be modeled as relationships such as mathematical relationships by machine-learning processes as described in further detail below. Training data 204 may be formatted and/or organized by categories of data elements, for instance by associating data elements with one or more descriptors corresponding to categories of data elements. As a non-limiting example, training data 204 may include data entered in standardized forms by persons or processes, such that entry of a given data element in a given field in a form may be mapped to one or more descriptors of categories. Elements in training data 204 may be linked to descriptors of categories by tags, tokens, or other data elements; for instance, and without limitation, training data 204 may be provided in fixed-length formats, formats linking positions of data to categories such as comma-separated value (CSV) formats and/or self-describing formats such as extensible markup language (XML), JavaScript Object Notation (JSON), or the like, enabling processes or devices to detect categories of data.

Alternatively or additionally, and continuing to refer to FIG. 2, training data 204 may include one or more elements that are not categorized; that is, training data 204 may not be formatted or contain descriptors for some elements of data. Machine-learning algorithms and/or other processes may sort training data 204 according to one or more categorizations using, for instance, natural language processing algorithms, tokenization, detection of correlated values in raw data and the like; categories may be generated using correlation and/or other processing algorithms. As a non-limiting example, in a corpus of text, phrases making up a number “n” of compound words, such as nouns modified by other nouns, may be identified according to a statistically significant prevalence of n-grams containing such words in a particular order; such an n-gram may be categorized as an element of language such as a “word” to be tracked similarly to single words, generating a new category as a result of statistical analysis. Similarly, in a data entry including some textual data, a person's name may be identified by reference to a list, dictionary, or other compendium of terms, permitting ad-hoc categorization by machine-learning algorithms, and/or automated association of data in the data entry with descriptors or into a given format. The ability to categorize data entries automatedly may enable the same training data 204 to be made applicable for two or more distinct machine-learning algorithms as described in further detail below. Training data 204 used by machine-learning module 200 may correlate any input data as described in this disclosure to any output data as described in this disclosure. As a non-limiting illustrative example, plurality of flagged data 128 as inputs correlated to examples of reservoir geometry 136 as outputs.

Further referring to FIG. 2, training data may be filtered, sorted, and/or selected using one or more supervised and/or unsupervised machine-learning processes and/or models as described in further detail below; such models may include without limitation a training data classifier 216. Training data classifier 216 may include a “classifier,” which as used in this disclosure is a machine-learning model as defined below, such as a data structure representing and/or using a mathematical model, neural net, or program generated by a machine learning algorithm known as a “classification algorithm,” as described in further detail below, that sorts inputs into categories or bins of data, outputting the categories or bins of data and/or labels associated therewith. A classifier may be configured to output at least a datum that labels or otherwise identifies a set of data that are clustered together, found to be close under a distance metric as described below, or the like. A distance metric may include any norm, such as, without limitation, a Pythagorean norm. Machine-learning module 200 may generate a classifier using a classification algorithm, defined as a processes whereby a computing device and/or any module and/or component operating thereon derives a classifier from training data 204. Classification may be performed using, without limitation, linear classifiers such as without limitation logistic regression and/or naive Bayes classifiers, nearest neighbor classifiers such as k-nearest neighbors classifiers, support vector machines, least squares support vector machines, fisher's linear discriminant, quadratic classifiers, decision trees, boosted trees, random forest classifiers, learning vector quantization, and/or neural network-based classifiers. As a non-limiting example, training data classifier 216 may classify elements of training data to according to the magnitude, duration, and style of pressure events that are being predicted by flagged data 128.

With further reference to FIG. 2, training examples for use as training data may be selected from a population of potential examples according to cohorts relevant to an analytical problem to be solved, a classification task, or the like. Alternatively or additionally, training data may be selected to span a set of likely circumstances or inputs for a machine-learning model and/or process to encounter when deployed. For instance, and without limitation, for each category of input data to a machine-learning process or model that may exist in a range of values in a population of phenomena such as images, user data, process data, physical data, or the like, a computing device, processor, and/or machine-learning model may select training examples representing each possible value on such a range and/or a representative sample of values on such a range. Selection of a representative sample may include selection of training examples in proportions matching a statistically determined and/or predicted distribution of such values according to relative frequency, such that, for instance, values encountered more frequently in a population of data so analyzed are represented by more training examples than values that are encountered less frequently. Alternatively or additionally, a set of training examples may be compared to a collection of representative values in a database and/or presented to a user, so that a process can detect, automatically or via user input, one or more values that are not included in the set of training examples. Computing device, processor, and/or module may automatically generate a missing training example; this may be done by receiving and/or retrieving a missing input and/or output value and correlating the missing input and/or output value with a corresponding output and/or input value collocated in a data record with the retrieved value, provided by a user and/or other device, or the like.

Still referring to FIG. 2, computer, processor, and/or module may be configured to sanitize training data. “Sanitizing” training data, as used in this disclosure, is a process whereby training examples are removed that interfere with convergence of a machine-learning model and/or process to a useful result. For instance, and without limitation, a training example may include an input and/or output value that is an outlier from typically encountered values, such that a machine-learning algorithm using the training example will be adapted to an unlikely amount as an input and/or output; a value that is more than a threshold number of standard deviations away from an average, mean, or expected value, for instance, may be eliminated. Alternatively or additionally, one or more training examples may identified as having poor quality data, where “poor quality” is defined as having a signal to noise ratio below a threshold value.

As a non-limiting example, and with further reference to FIG. 2, images used to train an image classifier or other machine-learning model and/or process that takes images as inputs or generates images as outputs may be rejected if image quality is below a threshold value. For instance, and without limitation, computing device, processor, and/or module may perform blur detection, and eliminate one or more Blur detection may be performed, as a non-limiting example, by taking Fourier transform, or an approximation such as a Fast Fourier Transform (FFT) of the image and analyzing a distribution of low and high frequencies in the resulting frequency-domain depiction of the image; numbers of high-frequency values below a threshold level may indicate blurriness. As a further non-limiting example, detection of blurriness may be performed by convolving an image, a channel of an image, or the like with a Laplacian kernel; this may generate a numerical score reflecting a number of rapid changes in intensity shown in the image, such that a high score indicates clarity, and a low score indicates blurriness. Blurriness detection may be performed using a gradient-based operator, which measures operators based on the gradient or first derivative of an image, based on the hypothesis that rapid changes indicate sharp edges in the image, and thus are indicative of a lower degree of blurriness. Blur detection may be performed using Wavelet-based operator, which takes advantage of the capability of coefficients of the discrete wavelet transform to describe the frequency and spatial content of images. Blur detection may be performed using statistics-based operators take advantage of several image statistics as texture descriptors in order to compute a focus level. Blur detection may be performed by using discrete cosine transform (DCT) coefficients in order to compute a focus level of an image from its frequency content.

Continuing to refer to FIG. 2, computing device, processor, and/or module may be configured to precondition one or more training examples. For instance, and without limitation, where a machine learning model and/or process has one or more inputs and/or outputs requiring, transmitting, or receiving a certain number of bits, samples, or other units of data, one or more training examples' elements to be used as or compared to inputs and/or outputs may be modified to have such a number of units of data. For instance, a computing device, processor, and/or module may convert a smaller number of units, such as in a low pixel count image, into a desired number of units, for instance by upsampling and interpolating. As a non-limiting example, a low pixel count image may have 100 pixels, however a desired number of pixels may be 128. Processor may interpolate the low pixel count image to convert the 100 pixels into 128 pixels. It should also be noted that one of ordinary skill in the art, upon reading this disclosure, would know the various methods to interpolate a smaller number of data units such as samples, pixels, bits, or the like to a desired number of such units. In some instances, a set of interpolation rules may be trained by sets of highly detailed inputs and/or outputs and corresponding inputs and/or outputs downsampled to smaller numbers of units, and a neural network or other machine learning model that is trained to predict interpolated pixel values using the training data. As a non-limiting example, a sample input and/or output, such as a sample picture, with sample-expanded data units (e.g., pixels added between the original pixels) may be input to a neural network or machine-learning model and output a pseudo replica sample-picture with dummy values assigned to pixels between the original pixels based on a set of interpolation rules. As a non-limiting example, in the context of an image classifier, a machine-learning model may have a set of interpolation rules trained by sets of highly detailed images and images that have been downsampled to smaller numbers of pixels, and a neural network or other machine learning model that is trained using those examples to predict interpolated pixel values in a facial picture context. As a result, an input with sample-expanded data units (the ones added between the original data units, with dummy values) may be run through a trained neural network and/or model, which may fill in values to replace the dummy values. Alternatively or additionally, processor, computing device, and/or module may utilize sample expander methods, a low-pass filter, or both. As used in this disclosure, a “low-pass filter” is a filter that passes signals with a frequency lower than a selected cutoff frequency and attenuates signals with frequencies higher than the cutoff frequency. The exact frequency response of the filter depends on the filter design. Computing device, processor, and/or module may use averaging, such as luma or chroma averaging in images, to fill in data units in between original data units.

In some embodiments, and with continued reference to FIG. 2, computing device, processor, and/or module may down-sample elements of a training example to a desired lower number of data elements. As a non-limiting example, a high pixel count image may have 256 pixels, however a desired number of pixels may be 128. Processor may down-sample the high pixel count image to convert the 256 pixels into 128 pixels. In some embodiments, processor may be configured to perform downsampling on data. Downsampling, also known as decimation, may include removing every Nth entry in a sequence of samples, all but every Nth entry, or the like, which is a process known as “compression,” and may be performed, for instance by an N-sample compressor implemented using hardware or software. Anti-aliasing and/or anti-imaging filters, and/or low-pass filters, may be used to clean up side-effects of compression.

Still referring to FIG. 2, machine-learning module 200 may be configured to perform a lazy-learning process 220 and/or protocol, which may alternatively be referred to as a “lazy loading” or “call-when-needed” process and/or protocol, may be a process whereby machine learning is conducted upon receipt of an input to be converted to an output, by combining the input and training set to derive the algorithm to be used to produce the output on demand. For instance, an initial set of simulations may be performed to cover an initial heuristic and/or “first guess” at an output and/or relationship. As a non-limiting example, an initial heuristic may include a ranking of associations between inputs and elements of training data 204. Heuristic may include selecting some number of highest-ranking associations and/or training data 204 elements. Lazy learning may implement any suitable lazy learning algorithm, including without limitation a K-nearest neighbors algorithm, a lazy naive Bayes algorithm, or the like; persons skilled in the art, upon reviewing the entirety of this disclosure, will be aware of various lazy-learning algorithms that may be applied to generate outputs as described in this disclosure, including without limitation lazy learning applications of machine-learning algorithms as described in further detail below.

Alternatively or additionally, and with continued reference to FIG. 2, machine-learning processes as described in this disclosure may be used to generate machine-learning models 224. A “machine-learning model,” as used in this disclosure, is a data structure representing and/or instantiating a mathematical and/or algorithmic representation of a relationship between inputs and outputs, as generated using any machine-learning process including without limitation any process as described above, and stored in memory; an input is submitted to a machine-learning model 224 once created, which generates an output based on the relationship that was derived. For instance, and without limitation, a linear regression model, generated using a linear regression algorithm, may compute a linear combination of input data using coefficients derived during machine-learning processes to calculate an output datum. As a further non-limiting example, a machine-learning model 224 may be generated by creating an artificial neural network, such as a convolutional neural network comprising an input layer of nodes, one or more intermediate layers, and an output layer of nodes. Connections between nodes may be created via the process of “training” the network, in which elements from a training data 204 set are applied to the input nodes, a suitable training algorithm (such as Levenberg-Marquardt, conjugate gradient, simulated annealing, or other algorithms) is then used to adjust the connections and weights between nodes in adjacent layers of the neural network to produce the desired values at the output nodes. This process is sometimes referred to as deep learning.

Still referring to FIG. 2, machine-learning algorithms may include at least a supervised machine-learning process 228. At least a supervised machine-learning process 228, as defined herein, include algorithms that receive a training set relating a number of inputs to a number of outputs, and seek to generate one or more data structures representing and/or instantiating one or more mathematical relations relating inputs to outputs, where each of the one or more mathematical relations is optimal according to some criterion specified to the algorithm using some scoring function. For instance, a supervised learning algorithm may include flagged data 128 as described above as inputs reservoir geometry 136 as outputs, and a scoring function representing a desired form of relationship to be detected between inputs and outputs; scoring function may, for instance, seek to maximize the probability that a given input and/or combination of elements inputs is associated with a given output to minimize the probability that a given input is not associated with a given output. Scoring function may be expressed as a risk function representing an “expected loss” of an algorithm relating inputs to outputs, where loss is computed as an error function representing a degree to which a prediction generated by the relation is incorrect when compared to a given input-output pair provided in training data 204. Persons skilled in the art, upon reviewing the entirety of this disclosure, will be aware of various possible variations of at least a supervised machine-learning process 228 that may be used to determine relation between inputs and outputs. Supervised machine-learning processes may include classification algorithms as defined above.

With further reference to FIG. 2, training a supervised machine-learning process may include, without limitation, iteratively updating coefficients, biases, weights based on an error function, expected loss, and/or risk function. For instance, an output generated by a supervised machine-learning model using an input example in a training example may be compared to an output example from the training example; an error function may be generated based on the comparison, which may include any error function suitable for use with any machine-learning algorithm described in this disclosure, including a square of a difference between one or more sets of compared values or the like. Such an error function may be used in turn to update one or more weights, biases, coefficients, or other parameters of a machine-learning model through any suitable process including without limitation gradient descent processes, least-squares processes, and/or other processes described in this disclosure. This may be done iteratively and/or recursively to gradually tune such weights, biases, coefficients, or other parameters. Updating may be performed, in neural networks, using one or more back-propagation algorithms. Iterative and/or recursive updates to weights, biases, coefficients, or other parameters as described above may be performed until currently available training data is exhausted and/or until a convergence test is passed, where a “convergence test” is a test for a condition selected as indicating that a model and/or weights, biases, coefficients, or other parameters thereof has reached a degree of accuracy. A convergence test may, for instance, compare a difference between two or more successive errors or error function values, where differences below a threshold amount may be taken to indicate convergence. Alternatively or additionally, one or more errors and/or error function values evaluated in training iterations may be compared to a threshold.

Still referring to FIG. 2, a computing device, processor, and/or module may be configured to perform method, method step, sequence of method steps and/or algorithm described in reference to this figure, in any order and with any degree of repetition. For instance, a computing device, processor, and/or module may be configured to perform a single step, sequence and/or algorithm repeatedly until a desired or commanded outcome is achieved; repetition of a step or a sequence of steps may be performed iteratively and/or recursively using outputs of previous repetitions as inputs to subsequent repetitions, aggregating inputs and/or outputs of repetitions to produce an aggregate result, reduction or decrement of one or more variables such as global variables, and/or division of a larger processing task into a set of iteratively addressed smaller processing tasks. A computing device, processor, and/or module may perform any step, sequence of steps, or algorithm in parallel, such as simultaneously and/or substantially simultaneously performing a step two or more times using two or more parallel threads, processor cores, or the like; division of tasks between parallel threads and/or processes may be performed according to any protocol suitable for division of tasks between iterations. Persons skilled in the art, upon reviewing the entirety of this disclosure, will be aware of various ways in which steps, sequences of steps, processing tasks, and/or data may be subdivided, shared, or otherwise dealt with using iteration, recursion, and/or parallel processing.

Further referring to FIG. 2, machine learning processes may include at least an unsupervised machine-learning processes 232. An unsupervised machine-learning process, as used herein, is a process that derives inferences in datasets without regard to labels; as a result, an unsupervised machine-learning process may be free to discover any structure, relationship, and/or correlation provided in the data. Unsupervised processes 232 may not require a response variable; unsupervised processes 232 may be used to find interesting patterns and/or inferences between variables, to determine a degree of correlation between two or more variables, or the like.

Still referring to FIG. 2, machine-learning module 200 may be designed and configured to create a machine-learning model 224 using techniques for development of linear regression models. Linear regression models may include ordinary least squares regression, which aims to minimize the square of the difference between predicted outcomes and actual outcomes according to an appropriate norm for measuring such a difference (e.g. a vector-space distance norm); coefficients of the resulting linear equation may be modified to improve minimization. Linear regression models may include ridge regression methods, where the function to be minimized includes the least-squares function plus term multiplying the square of each coefficient by a scalar amount to penalize large coefficients. Linear regression models may include least absolute shrinkage and selection operator (LASSO) models, in which ridge regression is combined with multiplying the least-squares term by a factor of 1 divided by double the number of samples. Linear regression models may include a multi-task lasso model wherein the norm applied in the least-squares term of the lasso model is the Frobenius norm amounting to the square root of the sum of squares of all terms. Linear regression models may include the elastic net model, a multi-task elastic net model, a least angle regression model, a LARS lasso model, an orthogonal matching pursuit model, a Bayesian regression model, a logistic regression model, a stochastic gradient descent model, a perceptron model, a passive aggressive algorithm, a robustness regression model, a Huber regression model, or any other suitable model that may occur to persons skilled in the art upon reviewing the entirety of this disclosure. Linear regression models may be generalized in an embodiment to polynomial regression models, whereby a polynomial equation (e.g. a quadratic, cubic or higher-order equation) providing a best predicted output/actual output fit is sought; similar methods to those described above may be applied to minimize error functions, as will be apparent to persons skilled in the art upon reviewing the entirety of this disclosure.

Continuing to refer to FIG. 2, machine-learning algorithms may include, without limitation, linear discriminant analysis. Machine-learning algorithm may include quadratic discriminant analysis. Machine-learning algorithms may include kernel ridge regression. Machine-learning algorithms may include support vector machines, including without limitation support vector classification-based regression processes. Machine-learning algorithms may include stochastic gradient descent algorithms, including classification and regression algorithms based on stochastic gradient descent. Machine-learning algorithms may include nearest neighbors algorithms. Machine-learning algorithms may include various forms of latent space regularization such as variational regularization. Machine-learning algorithms may include Gaussian processes such as Gaussian Process Regression. Machine-learning algorithms may include cross-decomposition algorithms, including partial least squares and/or canonical correlation analysis. Machine-learning algorithms may include naive Bayes methods. Machine-learning algorithms may include algorithms based on decision trees, such as decision tree classification or regression algorithms. Machine-learning algorithms may include ensemble methods such as bagging meta-estimator, forest of randomized trees, AdaBoost, gradient tree boosting, and/or voting classifier methods. Machine-learning algorithms may include neural net algorithms, including convolutional neural net processes.

Still referring to FIG. 2, a machine-learning model and/or process may be deployed or instantiated by incorporation into a program, apparatus, system and/or module. For instance, and without limitation, a machine-learning model, neural network, and/or some or all parameters thereof may be stored and/or deployed in any memory or circuitry. Parameters such as coefficients, weights, and/or biases may be stored as circuit-based constants, such as arrays of wires and/or binary inputs and/or outputs set at logic “1” and “0” voltage levels in a logic circuit to represent a number according to any suitable encoding system including twos complement or the like or may be stored in any volatile and/or non-volatile memory. Similarly, mathematical operations and input and/or output of data to or from models, neural network layers, or the like may be instantiated in hardware circuitry and/or in the form of instructions in firmware, machine-code such as binary operation code instructions, assembly language, or any higher-order programming language. Any technology for hardware and/or software instantiation of memory, instructions, data structures, and/or algorithms may be used to instantiate a machine-learning process and/or model, including without limitation any combination of production and/or configuration of non-reconfigurable hardware elements, circuits, and/or modules such as without limitation ASICs, production and/or configuration of reconfigurable hardware elements, circuits, and/or modules such as without limitation FPGAs, production and/or of non-reconfigurable and/or configuration non-rewritable memory elements, circuits, and/or modules such as without limitation non-rewritable ROM, production and/or configuration of reconfigurable and/or rewritable memory elements, circuits, and/or modules such as without limitation rewritable ROM or other memory technology described in this disclosure, and/or production and/or configuration of any computing device and/or component thereof as described in this disclosure. Such deployed and/or instantiated machine-learning model and/or algorithm may receive inputs from any other process, module, and/or component described in this disclosure, and produce outputs to any other process, module, and/or component described in this disclosure.

Continuing to refer to FIG. 2, any process of training, retraining, deployment, and/or instantiation of any machine-learning model and/or algorithm may be performed and/or repeated after an initial deployment and/or instantiation to correct, refine, and/or improve the machine-learning model and/or algorithm. Such retraining, deployment, and/or instantiation may be performed as a periodic or regular process, such as retraining, deployment, and/or instantiation at regular elapsed time periods, after some measure of volume such as a number of bytes or other measures of data processed, a number of uses or performances of processes described in this disclosure, or the like, and/or according to a software, firmware, or other update schedule. Alternatively or additionally, retraining, deployment, and/or instantiation may be event-based, and may be triggered, without limitation, by user inputs indicating sub-optimal or otherwise problematic performance and/or by automated field testing and/or auditing processes, which may compare outputs of machine-learning models and/or algorithms, and/or errors and/or error functions thereof, to any thresholds, convergence tests, or the like, and/or may compare outputs of processes described herein to similar thresholds, convergence tests or the like. Event-based retraining, deployment, and/or instantiation may alternatively or additionally be triggered by receipt and/or generation of one or more new training examples; a number of new training examples may be compared to a preconfigured threshold, where exceeding the preconfigured threshold may trigger retraining, deployment, and/or instantiation.

Still referring to FIG. 2, retraining and/or additional training may be performed using any process for training described above, using any currently or previously deployed version of a machine-learning model and/or algorithm as a starting point. Training data for retraining may be collected, preconditioned, sorted, classified, sanitized, or otherwise processed according to any process described in this disclosure. Training data may include, without limitation, training examples including inputs and correlated outputs used, received, and/or generated from any version of any system, module, machine-learning model or algorithm, apparatus, and/or method described in this disclosure; such examples may be modified and/or labeled according to user feedback or other processes to indicate desired results, and/or may have actual or measured results from a process being modeled and/or predicted by system, module, machine-learning model or algorithm, apparatus, and/or method as “desired” results to be compared to outputs for training processes as described above.

Redeployment may be performed using any reconfiguring and/or rewriting of reconfigurable and/or rewritable circuit and/or memory elements; alternatively, redeployment may be performed by production of new hardware and/or software components, circuits, instructions, or the like, which may be added to and/or may replace existing hardware and/or software components, circuits, instructions, or the like.

Further referring to FIG. 2, one or more processes or algorithms described above may be performed by at least a dedicated hardware unit 236. A “dedicated hardware unit,” for the purposes of this figure, is a hardware component, circuit, or the like, aside from a principal control circuit and/or processor performing method steps as described in this disclosure, that is specifically designated or selected to perform one or more specific tasks and/or processes described in reference to this figure, such as without limitation preconditioning and/or sanitization of training data and/or training a machine-learning algorithm and/or model. A dedicated hardware unit 236 may include, without limitation, a hardware unit that can perform iterative or massed calculations, such as matrix-based calculations to update or tune parameters, weights, coefficients, and/or biases of machine-learning models and/or neural networks, efficiently using pipelining, parallel processing, or the like; such a hardware unit may be optimized for such processes by, for instance, including dedicated circuitry for matrix and/or signal processing operations that includes, e.g., multiple arithmetic and/or logical circuit units such as multipliers and/or adders that can act simultaneously and/or in parallel or the like. Such dedicated hardware units 236 may include, without limitation, graphical processing units (GPUs), dedicated signal processing modules, FPGA or other reconfigurable hardware that has been configured to instantiate parallel processing units for one or more specific tasks, or the like, A computing device, processor, apparatus, or module may be configured to instruct one or more dedicated hardware units 236 to perform one or more operations described herein, such as evaluation of model and/or algorithm outputs, one-time or iterative updates to parameters, coefficients, weights, and/or biases, and/or any other operations such as vector and/or matrix operations as described in this disclosure.

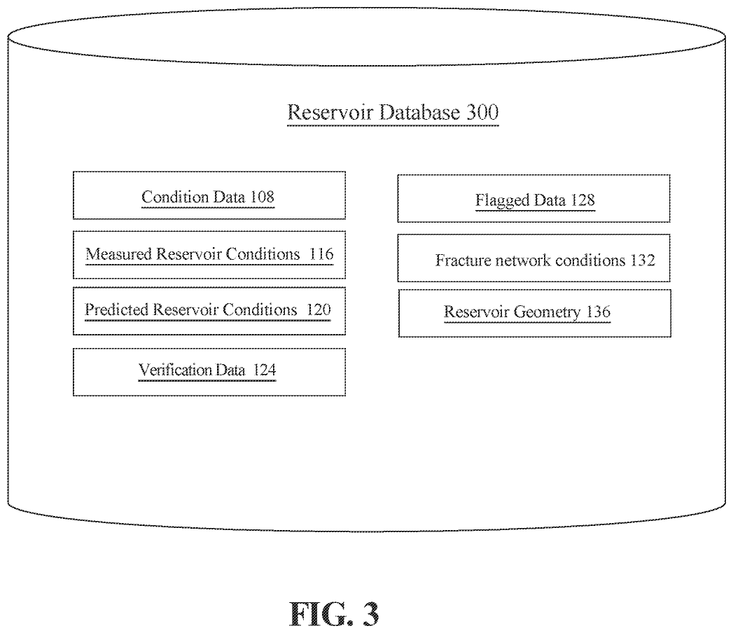

Now referring to FIG. 3, an exemplary reservoir database 300 is illustrated by way of block diagram. In an embodiment, any past or present versions of any data disclosed herein may be stored within the reservoir database 300 including but not limited to: condition data 108, measured reservoir data 116, verification data 124, expected reservoir conditions 120, flagged data 128, cleansed versions of the data, reservoir geometry 136, fracture network conditions 132, and the like. Processor 104 may be communicatively connected with reservoir database 300. For example, in some cases, database 300 may be local to processor 104. Alternatively or additionally, in some cases, database 300 may be remote to processor 104 and communicative with processor 104 by way of one or more networks. Network may include, but not limited to, a cloud network, a mesh network, or the like. By way of example, a “cloud-based” system, as that term is used herein, can refer to a system which includes software and/or data which is stored, managed, and/or processed on a network of remote servers hosted in the “cloud,” e.g., via the Internet, rather than on local severs or personal computers. A “mesh network” as used in this disclosure is a local network topology in which the infrastructure processor 104 connects directly, dynamically, and non-hierarchically to as many other computing devices as possible. A “network topology” as used in this disclosure is an arrangement of elements of a communication network. Reservoir database 300 may be implemented, without limitation, as a relational database, a key-value retrieval database such as a NOSQL database, or any other format or structure for use as a database that a person skilled in the art would recognize as suitable upon review of the entirety of this disclosure. Reservoir database 300 may alternatively or additionally be implemented using a distributed data storage protocol and/or data structure, such as a distributed hash table or the like. Reservoir database 300 may include a plurality of data entries and/or records as described above. Data entries in a database may be flagged with or linked to one or more additional elements of information, which may be reflected in data entry cells and/or in linked tables such as tables related by one or more indices in a relational database. Persons skilled in the art, upon reviewing the entirety of this disclosure, will be aware of various ways in which data entries in a database may store, retrieve, organize, and/or reflect data and/or records as used herein, as well as categories and/or populations of data consistently with this disclosure.

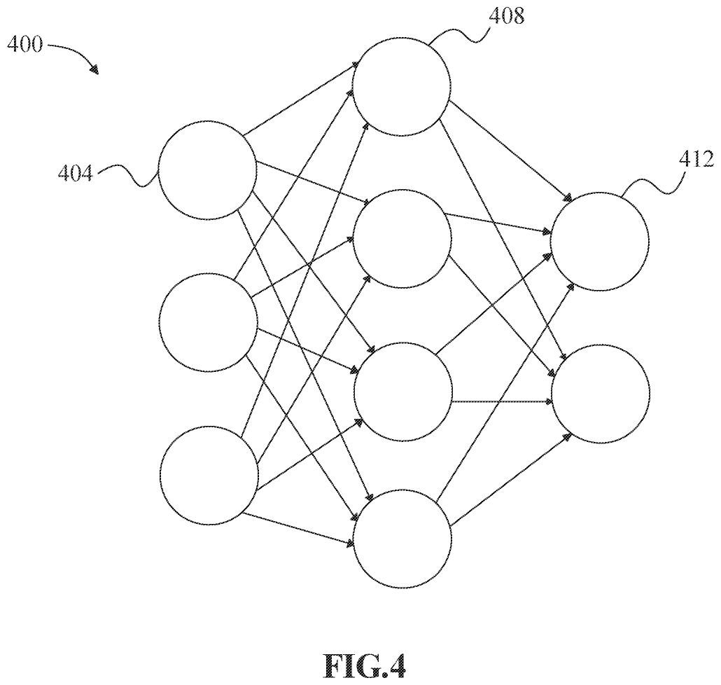

Referring now to FIG. 4, an exemplary embodiment of neural network 400 is illustrated. A neural network 400 also known as an artificial neural network, is a network of “nodes,” or data structures having one or more inputs, one or more outputs, and a function determining outputs based on inputs. Such nodes may be organized in a network, such as without limitation a convolutional neural network, including an input layer of nodes 404, one or more intermediate layers 408, and an output layer of nodes 412. Connections between nodes may be created via the process of “training” the network, in which elements from a training dataset are applied to the input nodes, a suitable training algorithm (such as Levenberg-Marquardt, conjugate gradient, simulated annealing, or other algorithms) is then used to adjust the connections and weights between nodes in adjacent layers of the neural network to produce the desired values at the output nodes. This process is sometimes referred to as deep learning. Connections may run solely from input nodes toward output nodes in a “feed-forward” network or may feed outputs of one layer back to inputs of the same or a different layer in a “recurrent network.” As a further non-limiting example, a neural network may include a convolutional neural network comprising an input layer of nodes, one or more intermediate layers, and an output layer of nodes. A “convolutional neural network,” as used in this disclosure, is a neural network in which at least one hidden layer is a convolutional layer that convolves inputs to that layer with a subset of inputs known as a “kernel,” along with one or more additional layers such as pooling layers, fully connected layers, and the like.

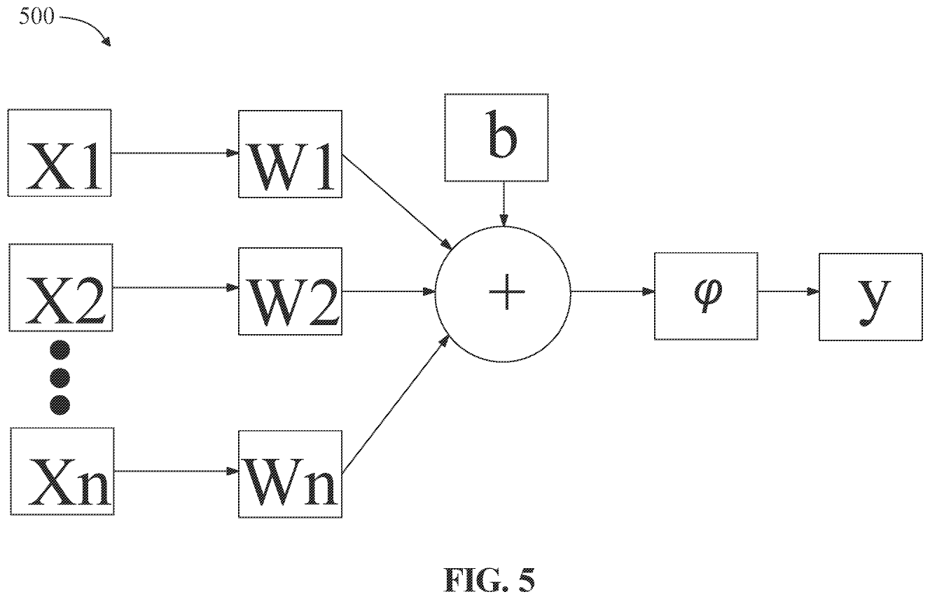

Referring now to FIG. 5, an exemplary embodiment of a node of a neural network is illustrated. A node may include, without limitation, a plurality of inputs xᵢ that may receive numerical values from inputs to a neural network containing the node and/or from other nodes. Node may perform a weighted sum of inputs using weights wᵢ that are multiplied by respective inputs xᵢ. Additionally or alternatively, a bias b may be added to the weighted sum of the inputs such that an offset is added to each unit in the neural network layer that is independent of the input to the layer. The weighted sum may then be input into a function φ, which may generate one or more outputs y. Weight wᵢ applied to an input xᵢ may indicate whether the input is “excitatory,” indicating that it has strong influence on the one or more outputs y, for instance by the corresponding weight having a large numerical value, and/or a “inhibitory,” indicating it has a weak effect influence on the one more inputs y, for instance by the corresponding weight having a small numerical value. The values of weights wᵢ may be determined by training a neural network using training data, which may be performed using any suitable process as described above.

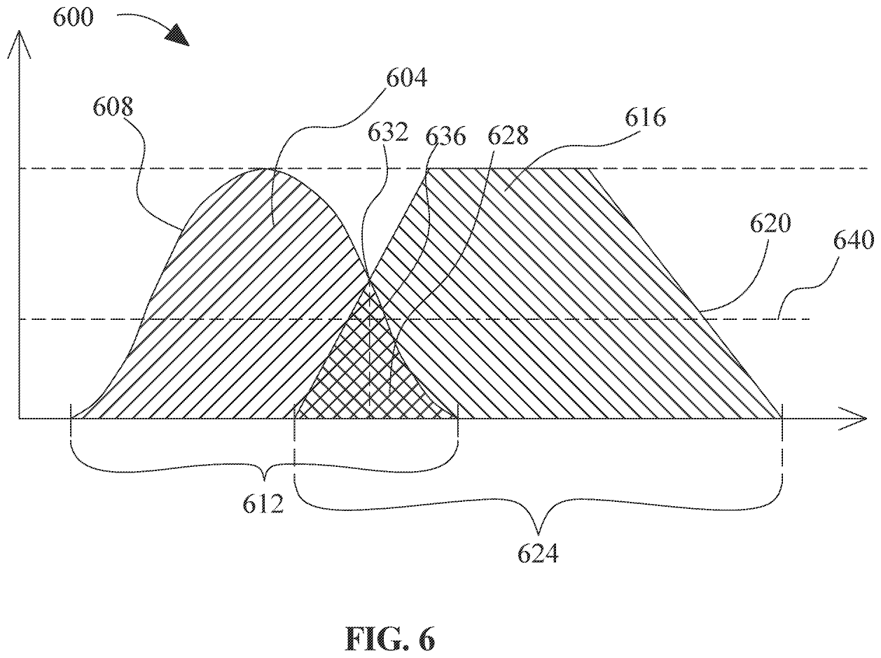

Now referring to FIG. 6, an exemplary embodiment of fuzzy set comparison 600 is illustrated. In a non-limiting embodiment, the fuzzy set comparison. In a non-limiting embodiment, fuzzy set comparison 600 may be consistent with fuzzy set comparison in FIG. 1. In another non-limiting the fuzzy set comparison 600 may be consistent with the name/version matching as described herein. For example and without limitation, the parameters, weights, and/or coefficients of the membership functions may be tuned using any machine-learning methods for the name/version matching as described herein. In another non-limiting embodiment, the fuzzy set may represent flagged data 128 and examples of reservoir geometry 136 from FIG. 1.

Alternatively or additionally, and still referring to FIG. 6, fuzzy set comparison 600 may be generated as a function of determining the data compatibility threshold. The compatibility threshold may be determined by a computing device. In some embodiments, a computing device may use a logic comparison program, such as, but not limited to, a fuzzy logic model to determine the compatibility threshold and/or version authenticator. Each such compatibility threshold may be represented as a value for a posting variable representing the compatibility threshold, or in other words a fuzzy set as described above that corresponds to a degree of compatibility and/or allowability as calculated using any statistical, machine-learning, or other method that may occur to a person skilled in the art upon reviewing the entirety of this disclosure. In some embodiments, determining the compatibility threshold and/or version authenticator may include using a linear regression model. A linear regression model may include a machine learning model. A linear regression model may map statistics such as, but not limited to, frequency of the same range of version numbers, and the like, to the compatibility threshold and/or version authenticator. In some embodiments, determining the compatibility threshold of any posting may include using a classification model. A classification model may be configured to input collected data and cluster data to a centroid based on, but not limited to, frequency of appearance of the range of versioning numbers, linguistic indicators of compatibility and/or allowability, and the like. Centroids may include scores assigned to them such that the compatibility threshold may each be assigned a score. In some embodiments, a classification model may include a K-means clustering model. In some embodiments, a classification model may include a particle swarm optimization model. In some embodiments, determining a compatibility threshold may include using a fuzzy inference engine. A fuzzy inference engine may be configured to map one or more compatibility threshold using fuzzy logic. In some embodiments, a plurality of computing devices may be arranged by a logic comparison program into compatibility arrangements. A “compatibility arrangement” as used in this disclosure is any grouping of objects and/or data based on skill level and/or output score. Membership function coefficients and/or constants as described above may be tuned according to classification and/or clustering algorithms. For instance, and without limitation, a clustering algorithm may determine a Gaussian or other distribution of questions about a centroid corresponding to a given compatibility threshold and/or version authenticator, and an iterative or other method may be used to find a membership function, for any membership function type as described above, that minimizes an average error from the statistically determined distribution, such that, for instance, a triangular or Gaussian membership function about a centroid representing a center of the distribution that most closely matches the distribution. Error functions to be minimized, and/or methods of minimization, may be performed without limitation according to any error function and/or error function minimization process and/or method as described in this disclosure.

Still referring to FIG. 6, inference engine may be implemented according to input flagged data 128 and examples of reservoir geometry 136. For instance, an acceptance variable may represent a first measurable value pertaining to the classification of flagged data 128 to examples of reservoir geometry 136. Continuing the example, an output variable may represent a reservoir geometry 136. In an embodiment, flagged data 128 and/or examples of reservoir geometry 136 may be represented by their own fuzzy set. In other embodiments, a reservoir geometry 136 may be represented as a function of the intersection two fuzzy sets as shown in FIG. 6, An inference engine may combine rules, such as any semantic versioning, semantic language, version ranges, and the like thereof. The degree to which a given input function membership matches a given rule may be determined by a triangular norm or “T-norm” of the rule or output function with the input function, such as min (a, b), product of a and b, drastic product of a and b, Hamacher product of a and b, or the like, satisfying the rules of commutativity (T(a, b)=T(b, a)), monotonicity: (T(a, b)≤T(c, d) if a≤c and b≤d), (associativity: T(a, T(b, c))=T(T(a, b), c)), and the requirement that the number 1 acts as an identity element. Combinations of rules (“and” or “or” combination of rule membership determinations) may be performed using any T-conorm, as represented by an inverted T symbol or “⊥,” such as max(a, b), probabilistic sum of a and b (a+b−a*b), bounded sum, and/or drastic T-conorm; any T-conorm may be used that satisfies the properties of commutativity: ⊥(a, b)=⊥(b, a), monotonicity: ⊥(a, b)≤⊥(c, d) if a≤c and b≤d, associativity: ⊥(a, ⊥(b, c))=⊥(⊥(a, b), c), and identity element of 0. Alternatively or additionally T-conorm may be approximated by sum, as in a “product-sum” inference engine in which T-norm is product and T-conorm is sum. A final output score or other fuzzy inference output may be determined from an output membership function as described above using any suitable defuzzification process, including without limitation Mean of Max defuzzification, Centroid of Area/Center of Gravity defuzzification, Center Average defuzzification, Bisector of Area defuzzification, or the like. Alternatively or additionally, output rules may be replaced with functions according to the Takagi-Sugeno-King (TSK) fuzzy model.

A first fuzzy set 604 may be represented, without limitation, according to a first membership function 608 representing a probability that an input falling on a first range of values 612 is a member of the first fuzzy set 604, where the first membership function 608 has values on a range of probabilities such as without limitation the interval [0,1], and an area beneath the first membership function 608 may represent a set of values within first fuzzy set 604. Although first range of values 612 is illustrated for clarity in this exemplary depiction as a range on a single number line or axis, first range of values 612 may be defined on two or more dimensions, representing, for instance, a Cartesian product between a plurality of ranges, curves, axes, spaces, dimensions, or the like. First membership function 608 may include any suitable function mapping first range 612 to a probability interval, including without limitation a triangular function defined by two linear elements such as line segments or planes that intersect at or below the top of the probability interval. As a non-limiting example, triangular membership function may be defined as:

$$( x , a , b , c ) = \{ \begin{matrix}0 , & for x > c and x < a \\ \frac{x - a}{b - a} , & for a \leq x < b \\ \frac{c - x}{c - b} , & if b < x \leq c\end{matrix}$$

a trapezoidal membership function may be defined as:

$$y ( x , a , b , c , d ) = max ( min ( \frac{x - a}{b - a} , 1 , \frac{d - x}{d - c} ) , 0 )$$

a sigmoidal function may be defined as:

$$y ( x , a , c ) = \frac{1}{1 - {e}^{- a ( x - c )}}$$

a Gaussian membership function may be defined as:

$$y ( x , c , σ ) = {e}^{- \frac{1}{2} {( \frac{x - c}{σ} )}^{2}}$$

and a bell membership function may be defined as:

$$y ( x , a , b , c , ) = {[ 1 + {\vert \frac{x - c}{a} \vert}^{2 b} ]}^{- 1}$$

Persons skilled in the art, upon reviewing the entirety of this disclosure, will be aware of various alternative or additional membership functions that may be used consistently with this disclosure.

First fuzzy set 604 may represent any value or combination of values as described above, including any flagged data 128 and examples of reservoir geometry 136. A second fuzzy set 616, which may represent any value which may be represented by first fuzzy set 604, may be defined by a second membership function 620 on a second range 624; second range 624 may be identical and/or overlap with first range 612 and/or may be combined with first range via Cartesian product or the like to generate a mapping permitting evaluation overlap of first fuzzy set 604 and second fuzzy set 616. Where first fuzzy set 604 and second fuzzy set 616 have a region 636 that overlaps, first membership function 608 and second membership function 620 may intersect at a point 632 representing a probability, as defined on probability interval, of a match between first fuzzy set 604 and second fuzzy set 616. Alternatively or additionally, a single value of first and/or second fuzzy set may be located at a locus 636 on first range 612 and/or second range 624, where a probability of membership may be taken by evaluation of first membership function 608 and/or second membership function 620 at that range point. A probability at 628 and/or 632 may be compared to a threshold 640 to determine whether a positive match is indicated. Threshold 640 may, in a non-limiting example, represent a degree of match between first fuzzy set 604 and second fuzzy set 616, and/or single values therein with each other or with either set, which is sufficient for purposes of the matching process; for instance, a reservoir geometry 136 may indicate a sufficient degree of overlap with fuzzy set representing flagged data 128 and examples of reservoir geometry 136 for combination to occur as described above. Each threshold may be established by one or more user inputs. Alternatively or additionally, each threshold may be tuned by a machine-learning and/or statistical process, for instance and without limitation as described in further detail below.

In an embodiment, a degree of match between fuzzy sets may be used to rank one resource against another. For instance, if both flagged data 128 and examples of reservoir geometry 136 have fuzzy sets, a reservoir geometry 136 may be generated by having a degree of overlap exceeding a predictive threshold, processor 104 may further rank the two resources by ranking a resource having a higher degree of match more highly than a resource having a lower degree of match. Where multiple fuzzy matches are performed, degrees of match for each respective fuzzy set may be computed and aggregated through, for instance, addition, averaging, or the like, to determine an overall degree of match, which may be used to rank resources; selection between two or more matching resources may be performed by selection of a highest-ranking resource, and/or multiple notifications may be presented to a user in order of ranking.

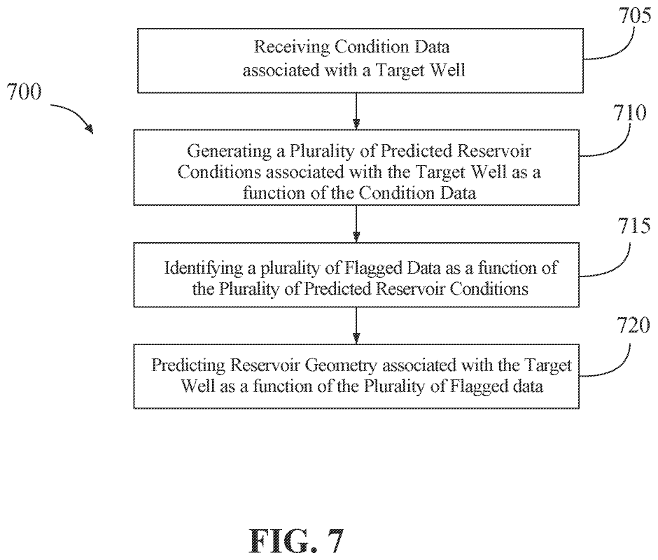

Referring now to FIG. 7, a flow diagram of an exemplary method 800 for generating a reservoir model is illustrated. At step 705, method 700 includes receiving, using at least a processor, a condition data associated with a target well. This may be implemented as described and with reference to FIGS. 1-6.

Still referring to FIG. 7, at step 710, method 700 includes generating, using the at least a processor, a plurality of reservoir conditions associated with the target well as a function of the condition data. This may be implemented as described and with reference to FIGS. 1-6. In an embodiment, the plurality of reservoir conditions may include reservoir pressure. In another embodiment, generating the reservoir conditions may include generating the plurality of reservoir conditions in real time. In some cases, the method may further include generating, using the at least a processor, verification data as a function of the plurality of reservoir conditions and a plurality of measured reservoir conditions.

Still referring to FIG. 7, at step 715, method 700 includes identifying, using the at least a processor, a plurality of flagged data as a function of the plurality of reservoir conditions. This may be implemented as described and with reference to FIGS. 1-6.

Still referring to FIG. 7, at step 720, method 700 includes predicting, using the at least a processor, reservoir geometry associated with the target well as a function of the plurality of flagged data This may be implemented as described and with reference to FIGS. 1-6. In an embodiment, predicting the reservoir geometry may include predicting the reservoir geometry in real time. In another embodiment, predicting the reservoir geometry further may include training a reservoir machine learning model using reservoir training data, wherein the reservoir training data comprises a plurality of flagged data correlated to examples of reservoir geometry and predicting the reservoir geometry as a function of the flagged data using a trained reservoir machine learning model. In some cases, wherein determining the reservoir geometry may include determining the reservoir geometry using a reservoir model. The method may include determining, using the at least a processor, fracture network conditions as a function of the flagged data. In an additional embodiment, wherein the method may include generating, using the at least a processor, a reservoir management recommendation as a function of the reservoir geometry. The geometry may include a three-dimensional representation of the target well.

It is to be noted that any one or more of the aspects and embodiments described herein may be conveniently implemented using one or more machines (e.g., one or more computing devices that are utilized as a user computing device for an electronic document, one or more server devices, such as a document server, etc.) programmed according to the teachings of the present specification, as will be apparent to those of ordinary skill in the computer art. Appropriate software coding can readily be prepared by skilled programmers based on the teachings of the present disclosure, as will be apparent to those of ordinary skill in the software art. Aspects and implementations discussed above employing software and/or software modules may also include appropriate hardware for assisting in the implementation of the machine executable instructions of the software and/or software module.

Such software may be a computer program product that employs a machine-readable storage medium. A machine-readable storage medium may be any medium that is capable of storing and/or encoding a sequence of instructions for execution by a machine (e.g., a computing device) and that causes the machine to perform any one of the methodologies and/or embodiments described herein. Examples of a machine-readable storage medium include, but are not limited to, a magnetic disk, an optical disc (e.g., CD, CD-R, DVD, DVD-R, etc.), a magneto-optical disk, a read-only memory “ROM” device, a random access memory “RAM” device, a magnetic card, an optical card, a solid-state memory device, an EPROM, an EEPROM, and any combinations thereof. A machine-readable medium, as used herein, is intended to include a single medium as well as a collection of physically separate media, such as, for example, a collection of compact discs or one or more hard disk drives in combination with a computer memory. As used herein, a machine-readable storage medium does not include transitory forms of signal transmission.

Such software may also include information (e.g., data) carried as a data signal on a data carrier, such as a carrier wave. For example, machine-executable information may be included as a data-carrying signal embodied in a data carrier in which the signal encodes a sequence of instruction, or portion thereof, for execution by a machine (e.g., a computing device) and any related information (e.g., data structures and data) that causes the machine to perform any one of the methodologies and/or embodiments described herein.

Examples of a computing device include, but are not limited to, an electronic book reading device, a computer workstation, a terminal computer, a server computer, a handheld device (e.g., a tablet computer, a smartphone, etc.), a web appliance, a network router, a network switch, a network bridge, any machine capable of executing a sequence of instructions that specify an action to be taken by that machine, and any combinations thereof. In one example, a computing device may include and/or be included in a kiosk.

FIG. 8 shows a diagrammatic representation of one embodiment of a computing device in the exemplary form of a computer system 800 within which a set of instructions for causing a control system to perform any one or more of the aspects and/or methodologies of the present disclosure may be executed. It is also contemplated that multiple computing devices may be utilized to implement a specially configured set of instructions for causing one or more of the devices to perform any one or more of the aspects and/or methodologies of the present disclosure. Computer system 800 includes a processor 804 and a memory 808 that communicate with each other, and with other components, via a bus 812. Bus 812 may include any of several types of bus structures including, but not limited to, a memory bus, a memory controller, a peripheral bus, a local bus, and any combinations thereof, using any of a variety of bus architectures.

Processor 804 may include any suitable processor, such as without limitation a processor incorporating logical circuitry for performing arithmetic and logical operations, such as an arithmetic and logic unit (ALU), which may be regulated with a state machine and directed by operational inputs from memory and/or sensors; processor 804 may be organized according to Von Neumann and/or Harvard architecture as a non-limiting example. Processor 804 may include, incorporate, and/or be incorporated in, without limitation, a microcontroller, microprocessor, digital signal processor (DSP), Field Programmable Gate Array (FPGA), Complex Programmable Logic Device (CPLD), Graphical Processing Unit (GPU), general purpose GPU, Tensor Processing Unit (TPU), analog or mixed signal processor, Trusted Platform Module (TPM), a floating point unit (FPU), and/or system on a chip (SoC).

Memory 808 may include various components (e.g., machine-readable media) including, but not limited to, a random-access memory component, a read only component, and any combinations thereof. In one example, a basic input/output system 816 (BIOS), including basic routines that help to transfer information between elements within computer system 800, such as during start-up, may be stored in memory 808. Memory 808 may also include (e.g., stored on one or more machine-readable media) instructions (e.g., software) 820 embodying any one or more of the aspects and/or methodologies of the present disclosure. In another example, memory 808 may further include any number of program modules including, but not limited to, an operating system, one or more application programs, other program modules, program data, and any combinations thereof.

Computer system 800 may also include a storage device 824. Examples of a storage device (e.g., storage device 824) include, but are not limited to, a hard disk drive, a magnetic disk drive, an optical disc drive in combination with an optical medium, a solid-state memory device, and any combinations thereof. Storage device 824 may be connected to bus 812 by an appropriate interface (not shown). Example interfaces include, but are not limited to, SCSI, advanced technology attachment (ATA), serial ATA, universal serial bus (USB), IEEE 1394 (FIREWIRE), and any combinations thereof. In one example, storage device 824 (or one or more components thereof) may be removably interfaced with computer system 800 (e.g., via an external port connector (not shown)). Particularly, storage device 824 and an associated machine-readable medium 828 may provide nonvolatile and/or volatile storage of machine-readable instructions, data structures, program modules, and/or other data for computer system 800. In one example, software 820 may reside, completely or partially, within machine-readable medium 828. In another example, software 820 may reside, completely or partially, within processor 804.

Computer system 800 may also include an input device 832. In one example, a user of computer system 800 may enter commands and/or other information into computer system 800 via input device 832. Examples of an input device 832 include, but are not limited to, an alpha-numeric input device (e.g., a keyboard), a pointing device, a joystick, a gamepad, an audio input device (e.g., a microphone, a voice response system, etc.), a cursor control device (e.g., a mouse), a touchpad, an optical scanner, a video capture device (e.g., a still camera, a video camera), a touchscreen, and any combinations thereof. Input device 832 may be interfaced to bus 812 via any of a variety of interfaces (not shown) including, but not limited to, a serial interface, a parallel interface, a game port, a USB interface, a FIREWIRE interface, a direct interface to bus 812, and any combinations thereof. Input device 832 may include a touch screen interface that may be a part of or separate from display 836, discussed further below. Input device 832 may be utilized as a user selection device for selecting one or more graphical representations in a graphical interface as described above.

A user may also input commands and/or other information to computer system 800 via storage device 824 (e.g., a removable disk drive, a flash drive, etc.) and/or network interface device 840. A network interface device, such as network interface device 840, may be utilized for connecting computer system 800 to one or more of a variety of networks, such as network 844, and one or more remote devices 848 connected thereto. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus, or other relatively small geographic space), a telephone network, a data network associated with a telephone/voice provider (e.g., a mobile communications provider data and/or voice network), a direct connection between two computing devices, and any combinations thereof. A network, such as network 844, may employ a wired and/or a wireless mode of communication. In general, any network topology may be used. Information (e.g., data, software 820, etc.) may be communicated to and/or from computer system 800 via network interface device 840.

Computer system 800 may further include a video display adapter 852 for communicating a displayable image to a display device, such as display device 836. Examples of a display device include, but are not limited to, a liquid crystal display (LCD), a cathode ray tube (CRT), a plasma display, a light emitting diode (LED) display, and any combinations thereof. Display adapter 852 and display device 836 may be utilized in combination with processor 804 to provide graphical representations of aspects of the present disclosure. In addition to a display device, computer system 800 may include one or more other peripheral output devices including, but not limited to, an audio speaker, a printer, and any combinations thereof. Such peripheral output devices may be connected to bus 812 via a peripheral interface 856. Examples of a peripheral interface include, but are not limited to, a serial port, a USB connection, a FIREWIRE connection, a parallel connection, and any combinations thereof.

The foregoing has been a detailed description of illustrative embodiments of the invention. Various modifications and additions can be made without departing from the spirit and scope of this invention. Features of each of the various embodiments described above may be combined with features of other described embodiments as appropriate in order to provide a multiplicity of feature combinations in associated new embodiments. Furthermore, while the foregoing describes a number of separate embodiments, what has been described herein is merely illustrative of the application of the principles of the present invention. Additionally, although particular methods herein may be illustrated and/or described as being performed in a specific order, the ordering is highly variable within ordinary skill to achieve methods, systems, and software according to the present disclosure. Accordingly, this description is meant to be taken only by way of example, and not to otherwise limit the scope of this invention.

Exemplary embodiments have been disclosed above and illustrated in the accompanying drawings. It will be understood by those skilled in the art that various changes, omissions, and additions may be made to that which is specifically disclosed herein without departing from the spirit and scope of the present invention.

1. An apparatus for generating a reservoir model, wherein the apparatus comprises:
at least a processor; and
a memory communicatively connected to the at least a processor, the memory containing instructions configuring the at least a processor to:
receive condition data associated with a target well;
generate a plurality of reservoir conditions associated with the target well as a function of the condition data;
identify a plurality of flagged data as a function of the plurality of reservoir conditions, wherein identifying the plurality of flagged data comprises:
receiving flag training data comprising a plurality of expected reservoir conditions correlated to examples of flagged data;
receiving past flagged data outputs of a machine learning model correlated to an accuracy score;
iteratively updating the flag training data based on a past flagged data classifier outputs;
training a flag data classifier using the updated flag training data; and
outputting, by the flag data classifier, the plurality of flagged data;
determine a reservoir geometry associated with the target well as a function of the plurality of flagged data; and
display the reservoir geometry, wherein displaying the reservoir geometry comprises generating a three-dimensional representation of the target well, wherein the reservoir geometry comprises isosurfaces that represent at least a reservoir property, and wherein the isosurfaces highlight regions of interest to users.

2. The apparatus of claim 1, wherein the memory further instructs the at least a processor to generate a pressure report as a function of the plurality of flagged data.

3. The apparatus of claim 1, wherein the memory further instructs the at least a processor to generate verification data as a function of the plurality of reservoir conditions and a plurality of measured reservoir conditions.

4. The apparatus of claim 1, wherein determining the reservoir geometry further comprises:
training a reservoir machine-learning model using reservoir training data, wherein the reservoir training data comprises a plurality of flagged data as inputs correlated to reservoir geometry as outputs; and
determining the reservoir geometry as a function of the flagged data using the reservoir machine-learning model.

5. The apparatus of claim 1, wherein determining the reservoir geometry comprises determining the reservoir geometry using a reservoir model.

6. The apparatus of claim 1, wherein the memory further instructs the at least a processor to determine fracture network conditions as a function of the plurality of flagged data and one or more fracture network conditions of a secondary well.

7. The apparatus of claim 6, wherein the memory further instructs the at least a processor to predict secondary well conditions as a function of the one or more fracture network conditions of the secondary well.

8. The apparatus of claim 6, wherein the memory further instructs the at least a processor to generate a fracture network management recommendation as a function of the one or more fracture network conditions of the secondary well.

9. The apparatus of claim 1, wherein the memory further instructs the at least a processor to generate a reservoir management recommendation as a function of the reservoir geometry.

10. (canceled)

11. A method for generating a reservoir model, wherein the method comprises:
receiving, using at least a processor, condition data associated with a target well;
generating, using the at least a processor, a plurality of reservoir conditions associated with the target well as a function of the condition data;
identifying, using the at least a processor, a plurality of flagged data as a function of the plurality of reservoir conditions, wherein identifying the plurality of flagged data comprises:
receiving flag training data comprising a plurality of expected reservoir conditions correlated to examples of flagged data;
receiving past flagged data outputs of a machine learning model correlated to an accuracy score;
iteratively updating the flag training data based on a past flagged data classifier outputs;
training a flag data classifier using the updated flag training data; and
outputting, by the flag data classifier, the plurality of flagged data;
determining, using the at least a processor, a reservoir geometry associated with the target well as a function of the plurality of flagged data; and
displaying, using the at least a processor, the reservoir geometry, wherein displaying the reservoir geometry comprises generating a three-dimensional representation of the target well, wherein the reservoir geometry comprises isosurfaces that represent at least a reservoir property, and wherein the isosurfaces highlight regions of interest to users.

12. The method of claim 11, wherein the method further comprises generating, using the at least a processor, a pressure report as a function of the plurality of flagged data.

13. The method of claim 11, wherein the method further comprises generating, using the at least a processor, verification data as a function of the plurality of reservoir conditions and a plurality of measured reservoir conditions.

14. The method of claim 11, wherein determining the reservoir geometry further comprises:
training a reservoir machine learning model using reservoir training data, wherein the reservoir training data comprises a plurality of flagged data as inputs correlated to examples of reservoir geometry as outputs; and
determining the reservoir geometry as a function of the flagged data using the reservoir machine learning model.

15. The method of claim 11, wherein determining the reservoir geometry comprises determining the reservoir geometry using a reservoir model.

16. The method of claim 11, wherein the method further comprises determining, using the at least a processor, fracture network conditions as a function of the plurality of flagged data and one or more fracture network conditions of a parent well.

17. The method of claim 16, wherein the method further comprises predicting, using the at least a processor, secondary well conditions as a function of the fracture network conditions of the secondary well.

18. The method of claim 16, wherein the method further comprises generating, using the at least a processor, a fracture network management recommendation as a function of the fracture network conditions of the secondary well.

19. The method of claim 11, wherein the method further comprises generating, using the at least a processor, a reservoir management recommendation as a function of the reservoir geometry.

20. (canceled)
